(19) United States
(12) Patent Application Publication
(10) Pub. No.: US 2025/0343513 A1
(43) Pub. Date: Nov. 6, 2025

(54) RADIO FREQUENCY MODULE AND COMMUNICATION DEVICE

(71) Applicant: Murata Manufacturing Co., Ltd., Nagaokakyo-shi (JP)

(72) Inventor: Kouta ARAI, Nagaokakyo-shi (JP)

(21) Appl. No.: 19/273,284

(22) Filed: Jul. 18, 2025

Related U.S. Application Data
(63) Continuation of application No. PCT/JP2023/045531, filed on Dec. 19, 2023.

(30) Foreign Application Priority Data
Feb. 9, 2023 (JP) 2023-018618

(51) Int. Cl. H03F 1/02; H03F 3/24; H04B 1/04

(52) U.S. Cl. CPC H03F 1/0233; H03F 3/245; H04B 1/04; H03F 2200/105; H03F 2200/451; H04B 2001/0408

(57) ABSTRACT

A radio frequency module is provided that includes a module laminate, a tracker circuit configured to generate a supply voltage to a power amplifier and composed of an integrated circuit, and an RFIC. The integrated circuit includes at least one switch included in a switched-capacitor circuit and at least one switch included in a supply modulator. The switched-capacitor circuit is configured to generate a plurality of discrete voltages based on an input voltage and output the generated plurality of discrete voltages to the supply modulator. The supply modulator is configured to selectively output at least one of the generated plurality of discrete voltages to the power amplifier. The RFIC and the integrated circuit are disposed on the module laminate.

### CROSS REFERENCE TO RELATED APPLICATIONS

This application is a continuation of International Application No. PCT/JP2023/045531, filed Dec. 19, 2023, which claims priority to Japanese Patent Application No. 2023-018618, filed Feb. 9, 2023, the contents of each of which are hereby incorporated by reference in their entireties.

### TECHNICAL FIELD

The present disclosure relates to a radio frequency module and a communication device.

### BACKGROUND

The recent application of an envelope tracking (ET) mode to a power amplifier (PA) circuit has improved power amplification efficiency. Moreover, U.S. Pat. No. 8,829,993 describes a digital ET technology for supplying a power supply voltage of a plurality of discrete voltage levels in the ET mode.

However, a power amplifier system (e.g., a radio frequency module) that operates in a digital ET mode requires a power amplifier (PA) circuit, a tracker circuit that supplies a digital ET mode power supply voltage to the power amplifier (PA), and a signal processing circuit that supplies a radio frequency (RF) signal to the PA circuit. This configuration can result in increasing the size of the power amplifier system.

### SUMMARY OF THE INVENTION

In view of the foregoing, the exemplary aspects of the present disclosure provide a small radio frequency module and a small communication device having an ET mode power amplifier system.

Specifically, in an exemplary aspect, a radio frequency module is provided that includes a module laminate; a first voltage supply circuit configured to generate a supply voltage to a first power amplifier (PA) that amplifies a radio frequency signal and composed of at least one integrated circuit; and a first signal processing circuit configured to output the radio frequency signal to an antenna. The at least one integrated circuit includes at least one switch included in a first switched-capacitor circuit and at least one switch included in a first supply modulator. Moreover, the first switched-capacitor circuit is configured to generate a plurality of discrete voltages based on an input voltage and output the generated plurality of discrete voltages to the first supply modulator. The first supply modulator is configured to selectively output at least one discrete voltage of the generated plurality of discrete voltages to the first PA, and the first signal processing circuit and the at least one integrated circuit providing the first voltage supply circuit are disposed on the module laminate.

Accordingly, the exemplary aspects of the present disclosure provide for a small radio frequency module and a small communication device having an ET mode power amplifier system.

### BRIEF DESCRIPTION OF DRAWINGS

FIG. 1A is a graph illustrating an example of the transition of a power supply voltage in an average power tracking (APT) mode.

FIG. 1B is a graph illustrating an example of the transition of the power supply voltage in an analog ET mode.

FIG. 1C is a graph illustrating an example of the transition of the power supply voltage in a digital ET mode.

FIG. 2 is a circuit configuration diagram of a radio frequency module and a communication device according to an exemplary embodiment.

FIG. 3 is a circuit configuration diagram of a pre-regulator circuit, a switched-capacitor circuit, a supply modulator, and a filter circuit according to the exemplary embodiment.

FIG. 4A is a plan view of a radio frequency module according to Example 1 of an exemplary aspect.

FIG. 4B is a cross-sectional view of the radio frequency module according to Example 1 of an exemplary aspect.

FIG. 5A is a plan view of a radio frequency module according to Example 2 of an exemplary aspect.

FIG. 5B is a cross-sectional view of the radio frequency module according to Example 2 of an exemplary aspect.

FIG. 6 is a plan view of a radio frequency module according to Example 3 of an exemplary aspect.

FIG. 7A is a plan view of a radio frequency module according to Example 4 of an exemplary aspect.

FIG. 7B is a cross-sectional view of the radio frequency module according to Example 4 of an exemplary aspect.

FIG. 8 is a cross-sectional view of a radio frequency module according to Example 5 of an exemplary aspect.

FIG. 9A is a plan view of a radio frequency module according to Example 6 of an exemplary aspect.

FIG. 9B is a plan view of the radio frequency module according to Example 6 of an exemplary aspect.

FIG. 9C is a cross-sectional view of the radio frequency module according to Example 6 of an exemplary aspect.

FIG. 10 is a plan view of a radio frequency module according to Example 7 of an exemplary aspect.

FIG. 11A is a plan view of a radio frequency module according to Example 8 of an exemplary aspect.

FIG. 11B is a plan view of the radio frequency module according to Example 8 of an exemplary aspect.

FIG. 11C is a cross-sectional view of the radio frequency module according to Example 8 of an exemplary aspect.

FIG. 12A is a plan view of a radio frequency module according to Example 9 of an exemplary aspect.

FIG. 12B is a plan view of the radio frequency module according to Example 9 of an exemplary aspect.

FIG. 12C is a cross-sectional view of the radio frequency module according to Example 9 of an exemplary aspect.

FIG. 13A is a plan view of a radio frequency module according to Example 10 of an exemplary aspect.

FIG. 13B is a plan view of the radio frequency module according to Example 10 of an exemplary aspect.

FIG. 13C is a cross-sectional view of the radio frequency module according to Example 10 of an exemplary aspect.

FIG. 14A is a plan view of a radio frequency module according to Example 11 of an exemplary aspect.

FIG. 14B is a plan view of the radio frequency module according to Example 11 of an exemplary aspect.

FIG. 14C is a cross-sectional view of the radio frequency module according to Example 11 of an exemplary aspect.

FIG. 15 is a cross-sectional view of a radio frequency module according to Example 12 of an exemplary aspect.

FIG. 16 is a cross-sectional view of a communications device according to Example 13 of an exemplary aspect.

### DETAILED DESCRIPTION OF EMBODIMENTS

Hereinafter, exemplary embodiments of the present disclosure will be described in detail with reference to the drawings. The embodiments described below are all comprehensive or specific examples. It is noted that according to the exemplary aspects, the numerical values, shapes, materials, components, arrangement and connection forms of the components illustrated in the following embodiments are merely examples and are not intended to limit the present disclosure.

It is also noted that each drawing is a schematic diagram in which emphasis, omission, or ratio adjustment has been applied as needed to illustrate the exemplary aspects of the present disclosure, and is thus not necessarily an exact illustration. Shapes, positional relationships, and ratios of each drawing are different from the actual ones in some cases. In each drawing, substantially the same configurations are denoted by the same reference numerals, and repetitive description thereof is omitted or simplified in some cases.

In each drawing described below, an x-axis and a y-axis are axes orthogonal to each other on a plane parallel to the main surfaces of a module laminate. Specifically, when a module laminate has a rectangular shape in plan view, the x-axis is parallel to a first side of the module laminate, and the y-axis is parallel to a second side orthogonal to the first side of the module laminate. Further, a z-axis is an axis perpendicular to the main surfaces of the module laminate. The positive direction of the z-axis indicates the upward direction, and the negative direction thereof indicates the downward direction.

In circuit configurations of the present disclosure, the term “connected” not only indicates that circuit elements are directly connected to each other with a connection terminal and/or a wire conductor, but it can also indicate that the circuit elements are electrically connected to each other via another circuit element according to an exemplary aspect. Also, the phrase “connected between A and B” indicates that a component is disposed between A and B and connected to both of A and B according to an exemplary aspect.

According to the exemplary aspects, in terms of the component placement of the present disclosure, the phrase “a component is placed on a substrate” includes a case where the component is placed on the main surface of the substrate and a case where the component is placed within the substrate. Specifically, the phrase “a component is placed on a substrate” includes, in addition to the case where the component is placed on the main surface of the substrate while being in contact with the main surface, the case where the component is placed above the main surface without being in contact with the main surface (for example, the component is stacked on another component placed in contact with the main surface). Further, the phrase “a component is placed on the main surface of a substrate” may include a case where a component is placed in a recess formed in the main surface. Moreover, the phrase “a component is placed within a substrate” includes a case where the component is encapsulated within a module laminate, as well as a case where the component is entirely placed between both main surfaces of the substrate but not entirely covered by the substrate, and a case where the component is only partially placed within the substrate.

In the present disclosure, the phrase “component (element) A is disposed in series with path B” can indicate that each of a signal input end and a signal output end of the component (element) A is connected to one of wiring, an electrode, and a terminal forming the path B according to an exemplary aspect.

Moreover, in terms of the component placement of the exemplary aspects of the present disclosure, the phrase “plan view of the module laminate” can refer to viewing an object or component orthographically projected on the xy plane from the positive side of the z-axis. The phrase “A overlaps B in plan view” can indicate that at least a part of the region of A orthographically projected on the xy plane overlaps at least a part of the region of B orthographically projected on the xy plane. Further, the phrase “A is disposed between B and C” can indicate that at least one of a plurality of line segments connecting any point in B and any point in C passes through A according to an exemplary aspect.

Further, in terms of the component placement of the exemplary aspects of the present disclosure, the phrase “A is disposed adjacent to B” can indicate that A and B are disposed in proximity to each other, and specifically can indicate that no other circuit components are present in the space where A faces B according to an exemplary aspect. In other words, the phrase “A is disposed adjacent to B” can indicate that none of a plurality of line segments that reach B from any point on a surface of A facing B along the normal direction of the surface passes through circuit components other than A and B. Here, the circuit components refer to components including active elements and/or passive elements. In other words, the circuit components include active components including transistors, diodes or the like, and passive components including inductors, transformers, capacitors, resistors or the like, but do not include electromechanical components including terminals, connectors, wiring or the like.

According to the exemplary aspects of the present disclosure, the term “terminal” refers to a point at which a conductor in an element ends. It is noted that when the impedance of the conductor between elements is sufficiently low, the terminal is interpreted not only as a single point, but also as any point on the conductor between elements or the entire conductor.

Further, terms indicating the relationship between elements, such as “parallel” and “perpendicular”, terms indicating the shapes of elements such as “rectangle”, and numerical value ranges do not only represent the strict meanings but also include substantially equivalent ranges with errors of about several percent, for example.

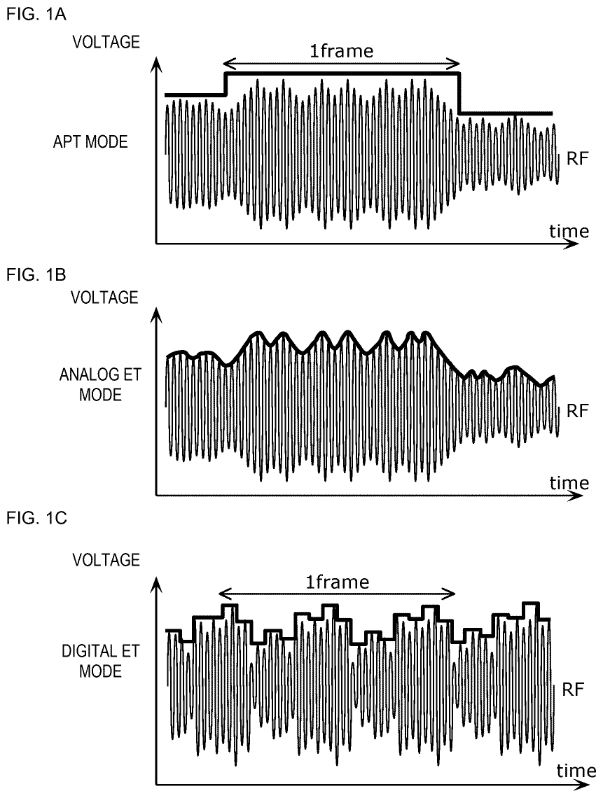

First, as a technology for amplifying a radio frequency (RF) signal with high efficiency, a description will be given of a tracking mode for supplying a power amplifier (PA) with a power supply voltage that is dynamically adjusted over time in accordance with the RF signal. The tracking mode is a mode for dynamically adjusting the power supply voltage applied to the PA. While there are several types of tracking modes, an average power tracking (APT) mode and an envelope tracking (ET) mode (including an analog ET mode and a digital ET mode) will be described here with reference to FIGS. 1A to 1C. In FIGS. 1A to 1C, the horizontal axis represents time and the vertical axis represents voltage. The thick solid line represents the power supply voltage, while the thin solid line (waveform) represents a modulated signal.

FIG. 1A is a graph illustrating an example of the transition of the power supply voltage in the APT mode. In the APT mode, the power supply voltage is varied to a plurality of discrete voltage levels in units of one frame, based on the average power. As a result, a power supply voltage signal forms a rectangular wave.

In an exemplary aspect, a frame refers to a unit that forms a radio frequency (RF) signal (e.g., a modulated signal). For example, in 5GNR (5th Generation New Radio) and LTE (Long Term Evolution), a frame includes 10 subframes, each subframe includes more than one slot, and each slot includes more than one symbol. The subframe length is 1 milliseconds (ms), and the frame length is 10 ms.

It is noted that a mode for changing the voltage level in units of one frame or larger based on the average power is referred to as the APT mode, and is distinguished from a mode for changing the voltage level in units smaller than one frame (such as the subframe, slot, or symbol). For example, a mode for changing the voltage level in units of symbols is referred to as a symbol power tracking (SPT) mode, and is distinguished from the APT mode.

FIG. 1B is a graph illustrating an example of the transition of the power supply voltage in the analog ET mode. In the analog ET mode, an envelope of the modulated signal is tracked by continuously changing the power supply voltage based on an envelope signal.

The envelope signal is a signal indicating the envelope of the modulated signal. The envelope value is expressed as the square root of (I²+Q²), for example. Here, (I, Q) represents a constellation point. The constellation point is a point on a constellation diagram that represents a signal modulated by digital modulation. (I, Q) is determined by a baseband integrated circuit (BBIC), for example, based on transmission information, for example.

FIG. 1C is a graph illustrating an example of the transition of the power supply voltage in the digital ET mode. In the digital ET mode, the envelope of the modulated signal is tracked by varying the power supply voltage to a plurality of discrete voltage levels within one frame, based on the envelope signal. As a result, the power supply voltage signal forms a rectangular wave.

### EXEMPLARY EMBODIMENT

A communication device 4 according to this embodiment corresponds to a user equipment (UE) that communicates with other terminals and base stations by using radio signals in the millimeter wave band or the sub-terahertz band. The communication device 4 is typically a mobile phone, a smartphone, a tablet computer, a wearable device, or the like. The communication device 4 may also be an IoT (Internet of Things) sensor device, a medical/healthcare device, a car, an unmanned aerial vehicle (UAV) (so-called drone), or an automated guided vehicle (AGV). The communication device 4 may also function as a base station. The communication device 4 may also be a UE or a base station in a cellular network.

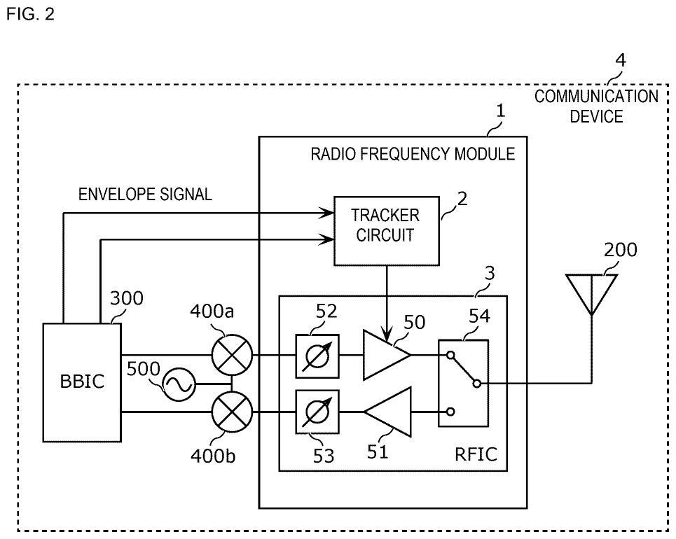

A circuit configuration of the communication device 4 and a radio frequency module 1 according to this embodiment will be described with reference to FIG. 2. FIG. 2 is a circuit configuration diagram of the radio frequency module 1 and the communication device 4 according to the embodiment.

It is noted that FIG. 2 illustrates an exemplary circuit configuration, and the communication device 4 and the radio frequency module 1 can be implemented using any of a wide variety of circuit implementations and circuit technologies. Therefore, the description of the communication device 4 and the radio frequency module 1 provided below should not be construed as being limiting.

### 1. Circuit Configuration of Communication Device 4 and Radio Frequency Module 1

First, the communication device 4 according to the embodiment will be described with reference to FIG. 2. The communication device 4 includes the radio frequency module 1, an antenna 200, a baseband signal integrated circuit (BBIC) 300, mixers 400a and 400b, and a local oscillator 500.

The radio frequency module 1 includes a tracker circuit 2 and an RFIC 3.

The RFIC (Radio Frequency Integrated Circuit) 3 is an example of a first signal processing circuit, and includes phase shift circuits 52 and 53, a power amplifier (PA) 50, a low-noise amplifier 51, and a switch 54. The RFIC 3 is configured to output a radio frequency signal to the antenna 200.

The phase shift circuit 52 is an example of a first phase shift circuit, and adjusts the phase of a radio frequency transmission signal outputted from the mixer 400a. The phase shift circuit 53 is an example of a second phase shift circuit, and adjusts the phase of a radio frequency reception signal outputted from the low-noise amplifier 51.

The PA 50 is an example of a first power amplifier, and amplifies the radio frequency transmission signal outputted from the phase shift circuit 52. The PA 50 includes a first amplifying transistor. The low-noise amplifier 51 amplifies the radio frequency reception signal outputted from the antenna 200.

The switch 54 switches the connection between the antenna 200 and the output end of the PA 50, and the connection between the antenna 200 and the input end of the low-noise amplifier 51.

In an exemplary aspect, the PA 50 and the low-noise amplifier 51 are configured to amplify radio frequency (RF) signals in the millimeter wave band and the sub-terahertz band. Moreover, the PA 50 and the low-noise amplifier 51 are configured to amplify RF signals in a frequency band predefined by a standardizing body (for example, 3GPP® (3rd Generation Partnership Project), IEEE (Institute of Electrical and Electronics Engineers) or the like) for a communication system built using a radio access technology (RAT).

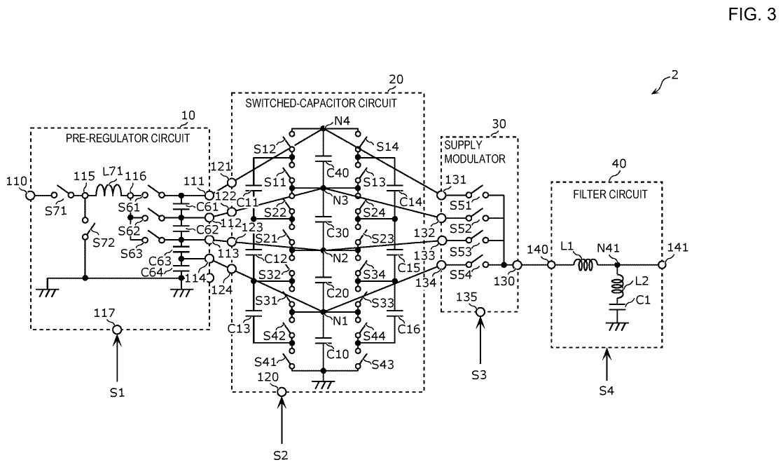

The tracker circuit 2 is an example of a first voltage supply circuit, and generates a supply voltage (a plurality of discrete voltages) to the PA 50, which amplifies a radio frequency signal, and is composed of at least one integrated circuit. Specifically, the tracker circuit 2 supplies a power supply voltage (a plurality of discrete voltages) to the PA 50 in the digital ET mode, based on an envelope signal supplied from the BBIC 300. A circuit configuration example of the tracker circuit 2 will be described later with reference to FIG. 3.

It is noted that at least one of the PA 50, the low-noise amplifier 51, and the switch 54 may be omitted from the RFIC 3 in an exemplary aspect.

The antenna 200 outputs the radio frequency transmission signal outputted from the radio frequency module 1, and also outputs the received radio frequency reception signal to the radio frequency module 1. It is noted that the antenna 200 may be omitted from the communication device 4 in an exemplary aspect.

The BBIC 300 is an integrated circuit that generates a baseband transmission signal and processes a baseband reception signal. The BBIC 300 also supplies an envelope signal to the tracker circuit 2 of the radio frequency module 1.

The mixer 400a up-converts the transmission signal generated by the BBIC 300, based on a local oscillation wave from the local oscillator 500, and outputs the up-converted transmission signal to a transmission path of the RFIC 3. The mixer 400b down-converts the reception signal outputted from a receive path of the RFIC 3, based on the local oscillation wave from the local oscillator 500, and outputs the down-converted reception signal to the BBIC 300.

It is noted that at least one of the mixers 400a and 400b and the local oscillator 500 may be included in the RFIC 3 in an exemplary aspect.

### 2. Circuit Configuration of Tracker Circuit 2

FIG. 3 is a circuit configuration diagram of a pre-regulator circuit 10, a switched-capacitor circuit 20, a supply modulator 30, and a filter circuit 40 according to the embodiment. The tracker circuit 2 can supply a plurality of discrete voltages to the PA 50, based on a tracking mode. The tracking mode can be, but is not limited to, the digital ET mode or the SPT mode. As illustrated in FIG. 3, the tracker circuit 2 includes the pre-regulator circuit 10, the switched-capacitor circuit 20, the supply modulator 30, and the filter circuit 40.

It is noted that FIG. 3 illustrates an exemplary circuit configuration, and the pre-regulator circuit 10, the switched-capacitor circuit 20, the supply modulator 30, and the filter circuit 40 can be implemented using any of a wide variety of circuit implementations and circuit technologies. Therefore, the description of each circuit provided below should not be construed as being limiting.

It is noted that the tracker circuit 2 may omit the filter circuit 40 in an exemplary aspect. Any combination of the pre-regulator circuit 10, the switched-capacitor circuit 20, the supply modulator 30, and the filter circuit 40 may be integrated into a single circuit. The tracker circuit 2 may also include a plurality of voltage supply circuits, instead of the pre-regulator circuit 10 and the switched-capacitor circuit 20. In this case, the supply modulator 30 may be configured to select at least one of the plurality of voltage supply circuits.

### [2.1 Circuit Configuration of Switched-Capacitor Circuit 20]

The switched-capacitor circuit 20 includes a plurality of capacitors and a plurality of switches, and can generate a plurality of second voltages, each having a plurality of discrete voltage levels, as a plurality of discrete voltages, from a first voltage from the pre-regulator circuit 10. The switched-capacitor circuit 20 is sometimes called a switched-capacitor voltage balancer.

As illustrated in FIG. 3, the switched-capacitor circuit 20 includes capacitors C11 to C16, capacitors C10, C20, C30, and C40, and switches S11 to S14, S21 to S24, S31 to S34, and S41 to S44. Energy and electric charges are received from the pre-regulator circuit 10 to the switched-capacitor circuit 20 at nodes N1 to N4, and are drawn from the switched-capacitor circuit 20 to the supply modulator 30 at the nodes N1 to N4.

The capacitors C11 to C16 each function as a flying capacitor (sometimes called a transfer capacitor). That is, the capacitors C11 to C16 are each used to step up or step down the first voltage supplied from the pre-regulator circuit 10. More specifically, the capacitors C11 to C16 transfer charges between the capacitors C11 to C16 and the nodes N1 to N4, so that voltages V1 to V4 (voltages with respect to a ground potential) that satisfy V1:V2:V3:V4=1:2:3:4 are maintained at the four nodes N1 to N4. These voltages V1 to V4 correspond to a plurality of second voltages, each having a plurality of discrete voltage levels.

The capacitor C11 has two electrodes. One of the two electrodes of the capacitor C11 is connected to one end of the switch S11 and one end of the switch S12. The other of the two electrodes of the capacitor C11 is connected to one end of the switch S21 and one end of the switch S22.

The capacitor C12 has two electrodes. One of the two electrodes of the capacitor C12 is connected to the one end of the switch S21 and the one end of the switch S22. The other of the two electrodes of the capacitor C12 is connected to one end of the switch S31 and one end of the switch S32.

The capacitor C13 has two electrodes. One of the two electrodes of the capacitor C13 is connected to the one end of the switch S31 and the one end of the switch S32. The other of the two electrodes of the capacitor C13 is connected to one end of the switch S41 and one end of the switch S42.

The capacitor C14 has two electrodes. One of the two electrodes of the capacitor C14 is connected to one end of the switch S13 and one end of the switch S14. The other of the two electrodes of the capacitor C14 is connected to one end of the switch S23 and one end of the switch S24.

The capacitor C15 has two electrodes. One of the two electrodes of the capacitor C15 is connected to the one end of the switch S23 and the one end of the switch S24. The other of the two electrodes of the capacitor C15 is connected to one end of the switch S33 and one end of the switch S34.

The capacitor C16 has two electrodes. One of the two electrodes of the capacitor C16 is connected to the one end of the switch S33 and the one end of the switch S34. The other of the two electrodes of the capacitor C16 is connected to one end of the switch S43 and one end of the switch S44.

A set of the capacitors C11 and C14, a set of the capacitors C12 and C15, and a set of the capacitors C13 and C16 can each be charged and discharged in a complementary manner as a result of a first phase and a second phase being repeated.

Specifically, in the first phase, the switches S12, S13, S22, S23, S32, S33, S42, and S43 are turned ON. Accordingly, for example, the one of the two electrodes of the capacitor C12 is connected to the node N3, the other of the two electrodes of the capacitor C12 and the one of the two electrodes of the capacitor C15 are connected to the node N2, and the other of the two electrodes of the capacitor C15 is connected to the node N1.

On the other hand, in the second phase, the switches S11, S14, S21, S24, S31, S34, S41, and S44 are turned ON. Accordingly, for example, the one of the two electrodes of the capacitor C15 is connected to the node N3, the other of the two electrodes of the capacitor C15 and the one of the two electrodes of the capacitor C12 are connected to the node N2, and the other of the two electrodes of the capacitor C12 is connected to the node N1.

As a result of the first phase and the second phase being repeated, for example, when one of the capacitors C12 and C15 is charged through the node N2, the other of the capacitors C12 and C15 can be discharged to the capacitor C30. In short, the capacitors C12 and C15 can be charged and discharged in a complementary manner.

Similarly to the set of the capacitors C12 and C15, the set of the capacitors C11 and C14 and the set of the capacitors C13 and C16 can each be charged and discharged in a complementary manner as a result of the first phase and the second phase being repeated.

The capacitors C10, C20, C30, and C40 each function as a smoothing capacitor. Specifically, the capacitors C10, C20, C30, and C40 are used to hold and smooth the voltages V1 to V4 at the nodes N1 to N4, respectively.

The capacitor C10 is connected between the node N1 and ground. Specifically, one of the two electrodes of the capacitor C10 is connected to the node N1. On the other hand, the other of the two electrodes of the capacitor C10 is connected to ground.

The capacitor C20 is connected between the nodes N2 and N1. Specifically, one of the two electrodes of the capacitor C20 is connected to the node N2. On the other hand, the other of the two electrodes of the capacitor C20 is connected to the node N1.

The capacitor C30 is connected between the nodes N3 and N2. Specifically, one of the two electrodes of the capacitor C30 is connected to the node N3. On the other hand, the other of the two electrodes of the capacitor C30 is connected to the node N2.

The capacitor C40 is connected between the nodes N4 and N3. Specifically, one of the two electrodes of the capacitor C40 is connected to the node N4. On the other hand, the other of the two electrodes of the capacitor C40 is connected to the node N3.

The switch S11 is connected between the one of the two electrodes of the capacitor C11 and the node N3. Specifically, the one end of the switch S11 is connected to the one of the two electrodes of the capacitor C11. On the other hand, the other end of the switch S11 is connected to the node N3.

The switch S12 is connected between the one of the two electrodes of the capacitor C11 and the node N4. Specifically, the one end of the switch S12 is connected to the one of the two electrodes of the capacitor C11. On the other hand, the other end of the switch S12 is connected to the node N4.

The switch S21 is connected between the one of the two electrodes of the capacitor C12 and the node N2. Specifically, the one end of the switch S21 is connected to the one of the two electrodes of the capacitor C12 and the other of the two electrodes of the capacitor C11. On the other hand, the other end of the switch S21 is connected to the node N2.

The switch S22 is connected between the one of the two electrodes of the capacitor C12 and the node N3. Specifically, the one end of the switch S22 is connected to the one of the two electrodes of the capacitor C12 and the other of the two electrodes of the capacitor C11. On the other hand, the other end of the switch S22 is connected to the node N3.

The switch S31 is connected between the other of the two electrodes of the capacitor C12 and the node N1. Specifically, the one end of the switch S31 is connected to the other of the two electrodes of the capacitor C12 and the one of the two electrodes of the capacitor C13. On the other hand, the other end of the switch S31 is connected to the node N1.

The switch S32 is connected between the other of the two electrodes of the capacitor C12 and the node N2. Specifically, the one end of the switch S32 is connected to the other of the two electrodes of the capacitor C12 and the one of the two electrodes of the capacitor C13. On the other hand, the other end of the switch S32 is connected to the node N2. That is, the other end of the switch S32 is connected to the other end of the switch S21.

The switch S41 is connected between the other of the two electrodes of the capacitor C13 and ground. Specifically, the one end of the switch S41 is connected to the other of the two electrodes of the capacitor C13. On the other hand, the other end of the switch S41 is connected to ground.

The switch S42 is connected between the other of the two electrodes of the capacitor C13 and the node N1. Specifically, the one end of the switch S42 is connected to the other of the two electrodes of the capacitor C13. On the other hand, the other end of the switch S42 is connected to the node N1. That is, the other end of the switch S42 is connected to the other end of the switch S31.

The switch S13 is connected between the one of the two electrodes of the capacitor C14 and the node N3. Specifically, the one end of the switch S13 is connected to the one of the two electrodes of the capacitor C14. On the other hand, the other end of the switch S13 is connected to the node N3. That is, the other end of the switch S13 is connected to the other end of the switch S11 and the other end of the switch S22.

The switch S14 is connected between the one of the two electrodes of the capacitor C14 and the node N4. Specifically, the one end of the switch S14 is connected to the one of the two electrodes of the capacitor C14. On the other hand, the other end of the switch S14 is connected to the node N4. That is, the other end of the switch S14 is connected to the other end of the switch S12.

The switch S23 is connected between the one of the two electrodes of the capacitor C15 and the node N2. Specifically, the one end of the switch S23 is connected to the one of the two electrodes of the capacitor C15 and the other of the two electrodes of the capacitor C14. On the other hand, the other end of the switch S23 is connected to the node N2. That is, the other end of the switch S23 is connected to the other end of the switch S21 and the other end of the switch S32.

The switch S24 is connected between the one of the two electrodes of the capacitor C15 and the node N3. Specifically, the one end of the switch S24 is connected to the one of the two electrodes of the capacitor C15 and the other of the two electrodes of the capacitor C14. On the other hand, the other end of the switch S24 is connected to the node N3. That is, the other end of the switch S24 is connected to the other end of the switch S11, the other end of the switch S22, and the other end of the switch S13.

The switch S33 is connected between the other of the two electrodes of the capacitor C15 and the node N1. Specifically, the one end of the switch S33 is connected to the other of the two electrodes of the capacitor C15 and the one of the two electrodes of the capacitor C16. On the other hand, the other end of the switch S33 is connected to the node N1. That is, the other end of the switch S33 is connected to the other end of the switch S31 and the other end of the switch S42.

The switch S34 is connected between the other of the two electrodes of the capacitor C15 and the node N2. Specifically, the one end of the switch S34 is connected to the other of the two electrodes of the capacitor C15 and the one of the two electrodes of the capacitor C16. On the other hand, the other end of the switch S34 is connected to the node N2. That is, the other end of the switch S34 is connected to the other end of the switch S21, the other end of the switch S32, and the other end of the switch S23.

The switch S43 is connected between the other of the two electrodes of the capacitor C16 and ground. Specifically, the one end of the switch S43 is connected to the other of the two electrodes of the capacitor C16. On the other hand, the other end of the switch S43 is connected to ground.

The switch S44 is connected between the other of the two electrodes of the capacitor C16 and the node N1. Specifically, the one end of the switch S44 is connected to the other of the two electrodes of the capacitor C16. On the other hand, the other end of the switch S44 is connected to the node N1. That is, the other end of the switch S44 is connected to the other end of the switch S31, the other end of the switch S42, and the other end of the switch S33.

The switches S11, S12, S13, S14, S21, S22, S23, and S24 are at least one switch included in the switched-capacitor circuit 20.

A first set of switches including the switches S12, S13, S22, S23, S32, S33, S42, and S43, and a second set of switches including the switches S11, S14, S21, S24, S31, S34, S41, and S44 are turned ON and OFF in a complementary manner based on a control signal S2. Specifically, in the first phase, the switches in the first set are turned ON whereas the switches in the second set are turned OFF. Conversely, in the second phase, the switches in the first set are turned OFF whereas the switches in the second set are turned ON.

For example, in one of the first phase and the second phase, charging from the capacitors C11 to C13 to the capacitors C10 to C40 is performed, and in the other of the first phase and the second phase, charging from the capacitors C14 to C16 to the capacitors C10 to C40 is performed. In other words, because the capacitors C10 to C40 are constantly charged by the capacitors C11 to C13 or the capacitors C14 to C16, the nodes N1 to N4 are rapidly replenished with electric charges even when currents rapidly flow from the nodes N1 to N4 to the supply modulator 30. Thus, potential variations at the nodes N1 to N4 can be reduced.

As a result of operating in the above-described manner, the switched-capacitor circuit 20 is configured to maintain substantially equal voltages across each of the capacitors C10, C20, C30, and C40. Specifically, the voltages V1 to V4 (voltages with respect to a ground potential) satisfying V1:V2:V3:V4=1:2:3:4 are maintained at the four nodes labeled V1 to V4. The levels of the voltages V1 to V4 correspond to a plurality of discrete voltage levels that can be supplied to the supply modulator 30 by the switched-capacitor circuit 20.

It is noted that the voltage ratio V1:V2:V3:V4 is not limited to 1:2:3:4. For example, the voltage ratio V1:V2:V3:V4 may be 1:2:4:8 in an alternative exemplary aspect.

The configuration of the switched-capacitor circuit 20 illustrated in FIG. 3 is illustrative and is not restrictive. In FIG. 3, the switched-capacitor circuit 20 is configured to supply voltages of four discrete voltage levels, but the configuration is not limited thereto. In an exemplary aspect, the switched-capacitor circuit 20 may be configured to supply voltages of any number of two or more discrete voltage levels. For example, in the case of supplying voltages of two discrete voltage levels, it is sufficient that the switched-capacitor circuit 20 include at least the capacitors C12 and C15 and the switches S21 to S24 and S31 to S34.

### [2.2 Circuit Configuration of Supply Modulator 30]

The supply modulator 30 is configured to selectively output at least one of the plurality of second voltages generated by the switched-capacitor circuit 20 to the PA 50. The supply modulator 30 is controlled based on a digital control signal.

As illustrated in FIG. 3, the supply modulator 30 includes input terminals 131 to 134, switches S51 to S54, and an output terminal 130.

The output terminal 130 is connected to an input terminal 140 of the filter circuit 40. The output terminal 130 is a terminal for supplying the PA 50 through the filter circuit 40 with a power supply voltage selected from among the voltages V1 to V4.

The input terminals 131 to 134 are connected to the nodes N4 to N1 of the switched-capacitor circuit 20, respectively. The input terminals 131 to 134 are terminals for receiving the voltages V4 to V1 from the switched-capacitor circuit 20, respectively.

The switch S51 is connected between the input terminal 131 and the output terminal 130. Specifically, the switch S51 has a terminal connected to the input terminal 131 and a terminal connected to the output terminal 130. In this connection configuration, ON/OFF switching of the switch S51 based on a control signal S3 enables switching between connection and disconnection between the input terminal 131 and the output terminal 130.

The switch S52 is connected between the input terminal 132 and the output terminal 130. Specifically, the switch S52 has a terminal connected to the input terminal 132 and a terminal connected to the output terminal 130. In this connection configuration, ON/OFF switching of the switch S52 based on the control signal S3 enables switching between connection and disconnection between the input terminal 132 and the output terminal 130.

The switch S53 is connected between the input terminal 133 and the output terminal 130. Specifically, the switch S53 has a terminal connected to the input terminal 133 and a terminal connected to the output terminal 130. In this connection configuration, ON/OFF switching of the switch S53 based on the control signal S3 enables switching between connection and disconnection between the input terminal 133 and the output terminal 130.

The switch S54 is connected between the input terminal 134 and the output terminal 130. Specifically, the switch S54 has a terminal connected to the input terminal 134 and a terminal connected to the output terminal 130. In this connection configuration, ON/OFF switching of the switch S54 based on the control signal S3 enables switching between connection and disconnection between the input terminal 134 and the output terminal 130.

The switches S51 and S52 are at least one switch included in the supply modulator 30.

These switches S51 to S54 are controlled so as to be exclusively turned ON. In other words, only any one of the switches S51 to S54 is turned ON, and the others are turned OFF. Accordingly, the supply modulator 30 is configured to output one voltage selected from among the voltages V1 to V4.

The configuration of the supply modulator 30 illustrated in FIG. 3 is illustrative, and is not restrictive. In particular, the switches S51 to S54 may have any configuration as long as at least one of the four input terminals 131 to 134 can be selected and connected to the output terminal 130. For example, the supply modulator 30 may further include a switch connected between a set of the switches S51 to S53 and a set of the switch S54 and the output terminal 130. For example, the supply modulator 30 may further include a switch connected between a set of the switches S51 and S52 and a set of the switches S53 and S54 and the output terminal 130.

In an exemplary aspect where voltages of two discrete voltage levels are supplied from the switched-capacitor circuit 20, it is sufficient that the supply modulator 30 include at least two of the switches S51 to S54.

### [2.3 Circuit Configuration of Pre-Regulator Circuit 10]

The pre-regulator circuit 10 is an example of a converter circuit, and includes a power inductor and switches. The power inductor is an inductor used to step up and/or step down a direct current (DC) voltage. The power inductor is connected in series to a direct current (DC) path. The power inductor may be connected (disposed in parallel) between the DC path and ground. The pre-regulator circuit 10 can convert an input voltage to a first voltage using the power inductor. Such a pre-regulator circuit 10 is also sometimes called a magnetic regulator or a DC/DC converter.

As illustrated in FIG. 3, the pre-regulator circuit 10 includes an input terminal 110, output terminals 111 to 114, inductor connection terminals 115 and 116, switches S61 to S63, S71, and S72, a power inductor L71, and capacitors C61 to C64.

The input terminal 110 is an input terminal for a DC voltage. Specifically, the input terminal 110 is a terminal for receiving an input voltage from a direct current (DC) power source.

The output terminal 111 is an output terminal for the voltage V4. Specifically, the output terminal 111 is a terminal for supplying the voltage V4 to the switched-capacitor circuit 20. The output terminal 111 is connected to the node N4 of the switched-capacitor circuit 20.

The output terminal 112 is an output terminal for the voltage V3. Specifically, the output terminal 112 is a terminal for supplying the voltage V3 to the switched-capacitor circuit 20. The output terminal 112 is connected to the node N3 of the switched-capacitor circuit 20.

The output terminal 113 is an output terminal for the voltage V2. Specifically, the output terminal 113 is a terminal for supplying the voltage V2 to the switched-capacitor circuit 20. The output terminal 113 is connected to the node N2 of the switched-capacitor circuit 20.

The output terminal 114 is an output terminal for the voltage V1. Specifically, the output terminal 114 is a terminal for supplying the voltage V1 to the switched-capacitor circuit 20. The output terminal 114 is connected to the node N1 of the switched-capacitor circuit 20.

The inductor connection terminal 115 is connected to one end of the power inductor L71. The inductor connection terminal 116 is connected to the other end of the power inductor L71.

The switch S71 is connected between the input terminal 110 and the one end of the power inductor L71. Specifically, the switch S71 has a terminal connected to the input terminal 110, and a terminal connected to the one end of the power inductor L71 via the inductor connection terminal 115. In this connection configuration, ON/OFF switching of the switch S71 based on a control signal S1 enables switching between connection and disconnection between the input terminal 110 and the one end of the power inductor L71.

The switch S72 is connected between the one end of the power inductor L71 and ground. Specifically, the switch S72 has a terminal connected to the one end of the power inductor L71 via the inductor connection terminal 115, and a terminal connected to ground. In this connection configuration, ON/OFF switching of the switch S72 based on the control signal S1 enables switching between connection and disconnection between the one end of the power inductor L71 and ground.

The switch S61 is connected between the other end of the power inductor L71 and the output terminal 111. Specifically, the switch S61 has a terminal connected to the other end of the power inductor L71 via the inductor connection terminal 116, and a terminal connected to the output terminal 111. In this connection configuration, ON/OFF switching of the switch S61 based on the control signal S1 enables switching between connection and disconnection between the other end of the power inductor L71 and the output terminal 111.

The switch S62 is connected between the other end of the power inductor L71 and the output terminal 112. Specifically, the switch S62 has a terminal connected to the other end of the power inductor L71 via the inductor connection terminal 116, and a terminal connected to the output terminal 112. In this connection configuration, ON/OFF switching of the switch S62 based on the control signal S1 enables switching between connection and disconnection between the other end of the power inductor L71 and the output terminal 112.

The switch S63 is connected between the other end of the power inductor L71 and the output terminal 113. Specifically, the switch S63 has a terminal connected to the other end of the power inductor L71 via the inductor connection terminal 116, and a terminal connected to the output terminal 113. In this connection configuration, ON/OFF switching of the switch S63 based on the control signal S1 enables switching between connection and disconnection between the other end of the power inductor L71 and the output terminal 113.

The switches S71 and S72 are at least one switch included in the pre-regulator circuit 10.

One of the two electrodes of the capacitor C61 is connected to the switch S61 and the output terminal 111. The other of the two electrodes of the capacitor C61 is connected to the switch S62, the output terminal 112, and one of the two electrodes of the capacitor C62. The capacitor C61 functions as a smoothing capacitor.

The one of the two electrodes of the capacitor C62 is connected to the switch S62, the output terminal 112, and the other of the two electrodes of the capacitor C61. The other of the two electrodes of the capacitor C62 is connected to a path connecting the switch S63, the output terminal 113, and one of the two electrodes of the capacitor C63.

The one of the two electrodes of the capacitor C63 is connected to the switch S63, the output terminal 113, and the other of the two electrodes of the capacitor C62. The other of the two electrodes of the capacitor C63 is connected to the output terminal 114 and one of the two electrodes of the capacitor C64.

The one of the two electrodes of the capacitor C64 is connected to the output terminal 114 and the other of the two electrodes of the capacitor C63. The other of the two electrodes of the capacitor C64 is connected to ground.

The switches S61 to S63 are controlled so as to be exclusively turned ON. In other words, only any one of the switches S61 to S63 is turned ON, and the others are turned OFF. Turning ON of only any one of the switches S61 to S63 enables the pre-regulator circuit 10 to change the voltage to be supplied to the switched-capacitor circuit 20 at the voltage levels of the voltages V2 to V4.

In an exemplary aspect, the pre-regulator circuit 10 configured as described above for supplying electric charges to the switched-capacitor circuit 20 via at least one of the output terminals 111 to 113.

In an exemplary aspect where an input voltage is converted into one first voltage, it is sufficient that the pre-regulator circuit 10 include at least the switches S71 and S72 and the power inductor L71.

### [2.4 Circuit Configuration of Filter Circuit 40]

The filter circuit 40 can attenuate noise from a plurality of discrete voltages supplied to the PA 50. The filter circuit 40 is also sometimes called a pulse shaping filter or a transition shaping filter.

As illustrated in FIG. 3, the filter circuit 40 includes inductors L1 and L2, a capacitor C1, an input terminal 140, and an output terminal 141.

The input terminal 140 is connected to the output terminal 130 of the supply modulator 30. The input terminal 140 is a terminal for receiving a voltage selected from among the plurality of discrete voltages by the supply modulator 30.

The output terminal 141 is an external connection terminal of the tracker circuit 2, and is connected to the PA 50 outside the tracker circuit 2. The output terminal 141 is a terminal for supplying a plurality of discrete voltages passing through the filter circuit 40 to the PA 50.

The inductor L1 is connected between the input terminal 140 and the output terminal 141. In other words, the inductor L1 is disposed in series with a path connecting the input terminal 140 and the output terminal 141. Specifically, one end of the inductor L1 is connected to the input terminal 140, and the other end of the inductor L1 is connected to the output terminal 141.

The inductor L2 is connected between a path connecting the inductor L1 and the output terminal 141 and ground. In other words, the inductor L2 is shunt connected to the path connecting the input terminal 140 and the output terminal 141. Specifically, one end of the inductor L2 is connected to the node N41 on the path connecting the inductor L1 and the output terminal 141, and the other end of the inductor L2 is connected to ground via the capacitor C1. It is noted that the inductor L2 may be connected between the capacitor C1 and ground, and may be omitted from the filter circuit 40 in an alternative exemplary aspect.

The capacitor C1 is connected between the inductor L2 and ground. In other words, the capacitor C1 is shunt connected to the path connecting the input terminal 140 and the output terminal 141. Specifically, one end of the capacitor C1 is connected to the inductor L2, and the other end of the capacitor C1 is connected to ground.

The filter circuit 40 may include a switch SW1 disposed in series with a path bypassing the inductor L1 between the input terminal 140 and the output terminal 141. This allows the filter circuit 40 to switch ON/OFF a band elimination filter for eliminating noise from a plurality of discrete voltages.

Such ON/OFF of the band elimination filter can be controlled based on a channel band width (that is, modulation band width) of a radio frequency (RF) signal RFA, for example. In an exemplary aspect where the PA 50 is configured to amplify transmission signals of a plurality of frequency bands, ON/OFF of the switch SW1 may be controlled based on the frequency band of the transmission signal amplified by the PA 50. It is noted that the control of the band elimination filter is not limited to the above. A circuit element other than the inductor L1 may be inserted into the path connecting the input terminal 140 and the output terminal 141.

The tracker circuit 2 may include a digital control circuit that processes a source-synchronous digital control signal received from the BBIC 300 to generate the control signals S1, S2, and S4. The control signal S1 is a signal for controlling ON/OFF of the switches S61 to S63, S71, and S72 included in the pre-regulator circuit 10. The control signal S2 is a signal for controlling ON/OFF of the switches S11 to S14, S21 to S24, S31 to S34, and S41 to S44 included in the switched-capacitor circuit 20. The control signal S4 is a signal for controlling ON/OFF of the switch SW1 included in the filter circuit 40.

The tracker circuit 2 may also include a digital control circuit that processes a digital control logic/line (DCL) signal received from the BBIC 300 to generate the control signal S3. The DCL signal is generated by the BBIC 300 based on an envelope signal of an RF signal or the like. The control signal S3 is a signal for controlling ON/OFF of the switches S51 to S54 included in the supply modulator 30.

### 3. Implementation Example of Radio Frequency Module 1A According to Example 1

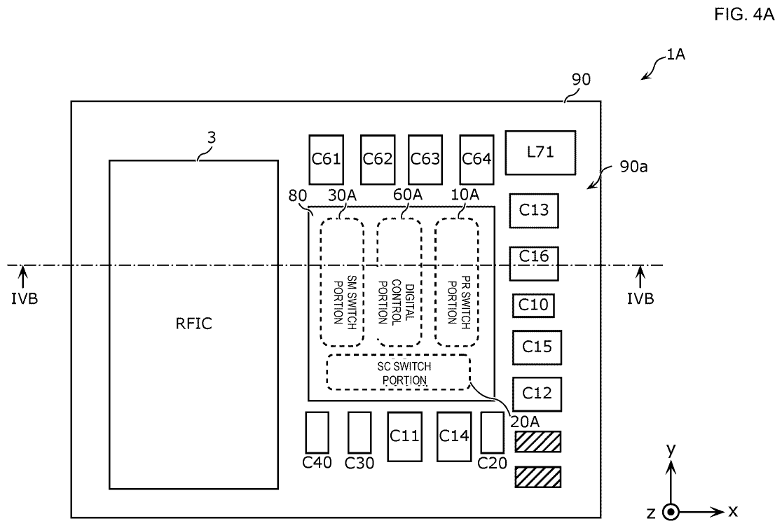

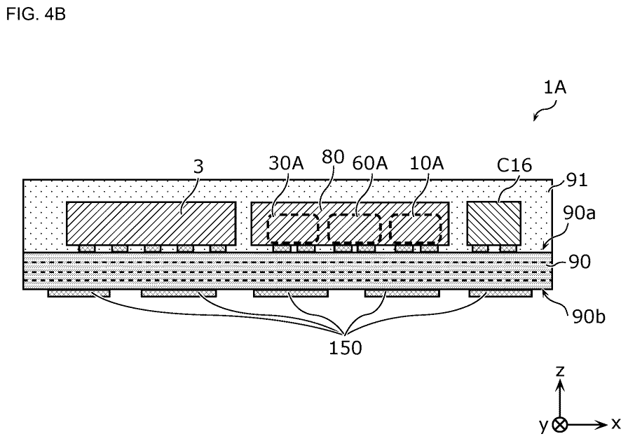

Next, as an implementation example of the radio frequency module 1 configured as described above, a radio frequency module 1A according to Example 1 will be described with reference to FIGS. 4A and 4B.

FIG. 4A is a plan view of the radio frequency module 1A according to Example 1. FIG. 4B is a cross-sectional view of the radio frequency module 1A according to Example 1. FIG. 4A illustrates a main surface 90a of a module laminate 90 viewed from the z-axis positive side. FIG. 4B illustrates a cross-section taken along line IVB-IVB in FIG. 4A.

In FIGS. 4A and 4B, some of the wiring connecting a plurality of circuit components disposed on the module laminate 90 is omitted. In FIGS. 4A and 4B, a shield electrode layer that covers the surface of a resin member 91 is omitted. It is noted that the resin member 91 and the shield electrode layer may be omitted according to alternative exemplary aspects. Moreover, in FIG. 4A, the hatched blocks represent optional circuit components that may be omitted according to alternative exemplary aspects of the present disclosure.

As illustrated in FIG. 4A, the radio frequency module 1A includes the module laminate 90, an RFIC 3, and an integrated circuit 80.

The module laminate 90 has the main surface 90a (first main surface) and a main surface 90b (second main surface) that face each other. A ground plane and the like are formed in the module laminate 90 and on the main surface 90a. In FIG. 4A, the module laminate 90 has a rectangular shape in plan view, but the shape of the module laminate 90 is not limited thereto.

For example, the module laminate 90 may be, but is not limited to, a low temperature co-fired ceramics (LTCC) substrate or a high temperature co-fired ceramics (HTCC) substrate having a multilayer structure of a plurality of dielectric layers, a component-embedded board, a substrate having a redistribution layer (RDL), or a printed circuit board.

The resin member 91 is disposed on the main surface 90a, covers the main surface 90a and some of the plurality of circuit components, and has a function to ensure the reliability of the plurality of circuit components, such as mechanical strength and moisture resistance.

The integrated circuit 80 is an example of a first integrated circuit, and is at least one integrated circuit included in the tracker circuit 2. The integrated circuit 80 is disposed on the main surface 90a of the module laminate 90, and includes a PR switch portion 10A, an SC switch portion 20A, an SM switch portion 30A, and a digital control portion 60A. The PR switch portion 10A includes switches S61 to S63, S71, and S72 of a pre-regulator circuit 10. The SC switch portion 20A includes switches S11 to S14, S21 to S24, S31 to S34, and S41 to S44 of a switched-capacitor circuit 20. The SM switch portion 30A includes switches S51 to S54 of a supply modulator 30. The digital control portion 60A includes a digital control circuit.

It is sufficient that the integrated circuit 80 include the SC switch portion 20A and the SM switch portion 30A, and it may omit the PR switch portion 10A or the digital control portion 60A in an alternative exemplary aspect.

In FIG. 4A, the integrated circuit 80 has a rectangular shape in plan view of the module laminate 90, but the shape of the integrated circuit 80 is not limited thereto.

The integrated circuit 80 is configured using, for example, a complementary metal oxide semiconductor (CMOS), and specifically may be manufactured by a silicon on insulator (SOI) process. The integrated circuit 80 is not limited to the CMOS.

The RFIC 3 is an example of a first signal processing circuit, and is disposed on the main surface 90a of the module laminate 90. It is noted that the RFIC 3 according to this example may omit a power amplifier (PA) 50.

With the above configuration, the density of circuit components on the module laminate 90 in this example can be made higher than the density of circuit components on a motherboard in accordance with the design rules for the motherboard of a communication device 4, for example. Therefore, the radio frequency module 1A according to this example can be reduced in size, compared to a configuration in which the integrated circuit 80 and the RFIC 3 are individually disposed on the motherboard. Accordingly, this configuration provides a small radio frequency module 1A and a small communication device 4 having an ET mode power amplifier system.

As illustrated in FIGS. 4A and 4B, the RFIC 3 and the integrated circuit 80 are disposed adjacent to each other on the main surface 90a.

Thus, the radio frequency module 1A can be further reduced in size.

The radio frequency module 1A further includes capacitors C61 to C64 and a power inductor L71 included in the pre-regulator circuit 10, and capacitors C11 to C16 and capacitors C10 to C40 included in the switched-capacitor circuit 20.

The capacitors C61 to C64 and the power inductor L71, as well as the capacitors C11 to C16 and the capacitors C10 to C40 are disposed on the main surface 90a.

The capacitors C61 to C64, the capacitors C11 to C16, and the capacitors C10 to C40 are each implemented as a chip capacitor. In an exemplary aspect, the chip capacitor can be a surface mount device (SMD) forming a capacitor. The implementation of the plurality of capacitors is not limited to chip capacitors. For example, some or all of the plurality of capacitors may be included in an integrated passive device (IPD), or may be included in the integrated circuit 80.

In this way, the plurality of capacitors and the inductor disposed on the main surface 90a are grouped for the individual circuits and disposed around the integrated circuit 80.

Specifically, a group of the capacitors C61 to C64 and the power inductor L71 included in the pre-regulator circuit 10 is disposed in a region on the main surface 90a sandwiched between a straight line along the upper side of the integrated circuit 80 and a straight line along the upper side of the module laminate 90 in plan view of the module laminate 90. Accordingly, a group of the circuit components included in the pre-regulator circuit 10 is disposed near the PR switch portion 10A disposed in the upper part of the integrated circuit 80.

A group of the capacitors C11 to C16 and the capacitors C10 to C40 included in the switched-capacitor circuit 20 is disposed in a region on the main surface 90a sandwiched between a straight line along the right side of the integrated circuit 80 and a straight line along the right side of the module laminate 90, and a region on the main surface 90a sandwiched between a straight line along the lower side of the integrated circuit 80 and a straight line along the lower side of the module laminate 90, in plan view of the module laminate 90. Accordingly, a group of the circuit components included in the switched-capacitor circuit 20 is disposed near the SC switch portion 20A disposed in the lower part of the integrated circuit 80.

Accordingly, wiring loss in the pre-regulator circuit 10 and the switched-capacitor circuit 20 can be reduced, and power consumption can be reduced.

### 4. Implementation Example of Radio Frequency Module 1B According to Example 2

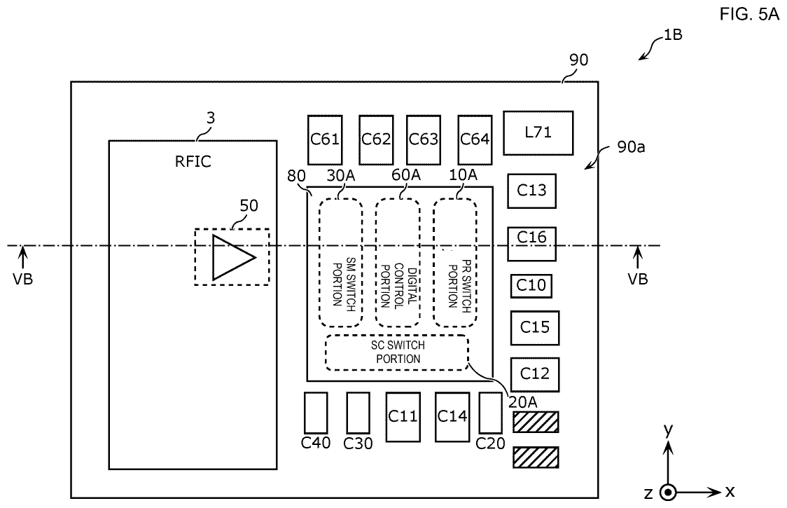

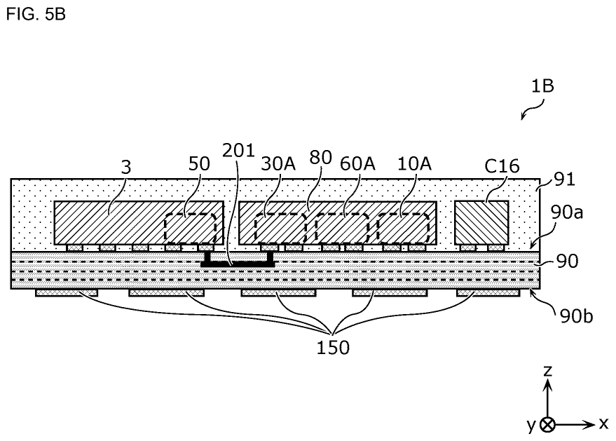

FIG. 5A is a plan view of a radio frequency module 1B according to Example 2. FIG. 5B is a cross-sectional view of the radio frequency module 1B according to Example 2. FIG. 5A illustrates a main surface 90a of a module laminate 90 viewed from the z-axis positive side. FIG. 5B illustrates a cross-section taken along line VB-VB in FIG. 5A.

As illustrated in FIG. 5A, the radio frequency module 1B includes the module laminate 90, an RFIC 3, and an integrated circuit 80. The radio frequency module 1B according to this example differs in the configuration from the radio frequency module 1A according to Example 1 in that the RFIC 3 includes a power amplifier (PA) 50. Hereinafter, regarding the radio frequency module 1B according to this example, descriptions of the same points as those of the radio frequency module 1A according to Example 1 will be omitted, and differences will be mainly described.

The RFIC 3 is an example of a first signal processing circuit, and includes the PA 50. The RFIC 3 is disposed on the main surface 90a of the module laminate 90. The PA 50 and the integrated circuit 80 are disposed adjacent to each other on the main surface 90a.

Accordingly, a small radio frequency module 1B having an ET mode power amplifier system can be provided. As illustrated in FIG. 5B, wiring 201 for supplying a supply voltage (a plurality of discrete voltages) from a tracker circuit 2 to the PA 50 can be shortened, and thus the supply voltage can be stabilized.

Here, as illustrated in FIGS. 5A and 5B, an SM switch portion 30A is disposed closest to the PA 50, among a PR switch portion 10A, an SC switch portion 20A, the SM switch portion 30A, and a digital control portion 60A.

Accordingly, the wiring 201 connecting the PA 50 and the SM switch portion 30A can be shortened, and thus the supply voltage can be stabilized.

### 5. Implementation Example of Radio Frequency Module 1C According to Example 3

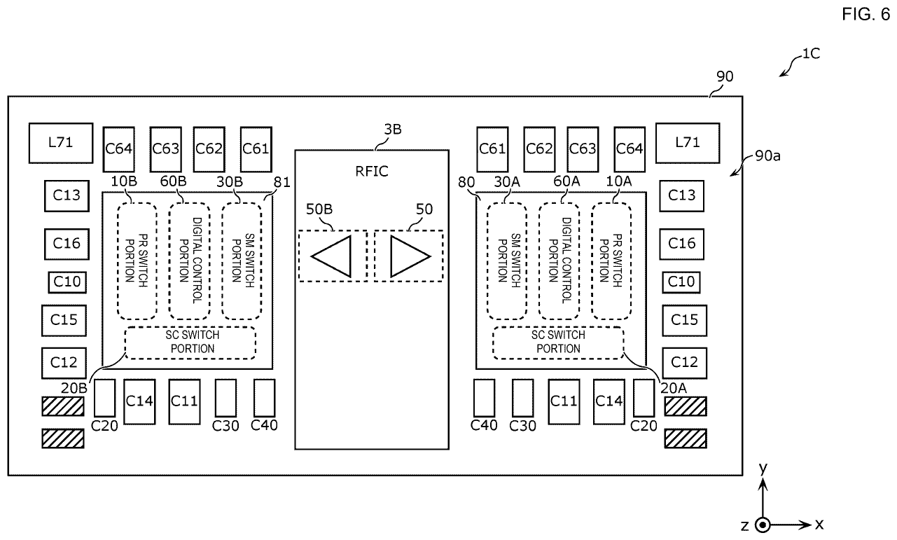

FIG. 6 is a plan view of a radio frequency module 1C according to Example 3. FIG. 6 illustrates a main surface 90a of a module laminate 90 viewed from the z-axis positive side.

As illustrated in FIG. 6, the radio frequency module 1C includes the module laminate 90, an RFIC 3B, and integrated circuits 80 and 81. The radio frequency module 1C according to this example differs in the configuration from the radio frequency module 1B according to Example 2 in including the integrated circuits 80 and 81, and in that the RFIC 3B includes power amplifiers (PAs) 50 and 50B. Hereinafter, regarding the radio frequency module 1C according to this example, descriptions of the same points as those of the radio frequency module 1B according to Example 2 will be omitted, and differences will be mainly described.

The RFIC 3B is an example of a first signal processing circuit, and includes the PAs 50 and 50B. The PA 50 is an example of a first power amplifier (PA) and amplifies a radio frequency signal. The PA 50B is an example of a second power amplifier (PA) and amplifies a radio frequency signal. The PA 50B includes a second amplifying transistor.

The radio frequency module 1C includes a second voltage supply circuit in addition to a tracker circuit 2 (first voltage supply circuit). In an exemplary aspect, the second voltage supply circuit can include a pre-regulator circuit, a switched-capacitor circuit, and a supply modulator. The second voltage supply circuit generates a supply voltage (a plurality of discrete voltages) to the PA 50B that amplifies the radio frequency signal, and is composed of at least one integrated circuit. The pre-regulator circuit 310 has the same circuit configuration as that of the pre-regulator circuit 10. The switched-capacitor circuit 320 has the same circuit configuration as that of the switched-capacitor circuit 20. The supply modulator 330 has the same circuit configuration as that of the supply modulator 30.

The integrated circuit 81 is an example of a second integrated circuit, and is at least one integrated circuit included in the second voltage supply circuit. The integrated circuit 81 is disposed on the main surface 90a of the module laminate 90, and includes a PR switch portion 10B, an SC switch portion 20B, an SM switch portion 30B, and a digital control portion 60B. The PR switch portion 10B includes switches S61 to S63, S71, and S72 of the pre-regulator circuit 310. The SC switch portion 20B includes switches S11 to S14, S21 to S24, S31 to S34, and S41 to S44 of the switched-capacitor circuit 320. The SM switch portion 30B includes switches S51 to S54 of the supply modulator 330. The digital control portion 60B includes a digital control circuit.

It is sufficient that the integrated circuit 81 include the SC switch portion 20B and the SM switch portion 30B, and it may omit the PR switch portion 10B or the digital control portion 60B in an alternative exemplary aspect.

The RFIC 3B and the integrated circuits 80 and 81 are disposed on the main surface 90a of the module laminate 90. The PA 50 and the integrated circuit 80 are disposed adjacent to each other, and the PA 50B and the integrated circuit 81 are disposed adjacent to each other. In plan view of the main surface 90a of the module laminate 90, the RFIC 3B is disposed between the integrated circuit 80 and the integrated circuit 81.

Accordingly, the radio frequency module 1C can be reduced in size, compared with a case where the integrated circuits 80 and 81 and the RFIC 3B are disposed individually on a motherboard. Wiring for supplying a supply voltage (a plurality of discrete voltages) from the tracker circuit 2 to the PA 50 and wiring for supplying a supply voltage (a plurality of discrete voltages) from the second voltage supply circuit to the PA 50B can be shortened. Thus, the supply voltages can be stabilized.

The PA 50 and the PA 50B are not connected in series. In other words, the PA 50 is disposed in series with a first path connecting a first radio frequency (RF) signal input terminal and a first RF signal output terminal of the RFIC 3B. The PA 50B is disposed in series with a second path connecting a second RF signal input terminal and a second RF signal output terminal of the RFIC 3B. The first path and the second path are different paths.

The radio frequency module 1C further includes capacitors C61 to C64 and a power inductor L71 included in the pre-regulator circuit 10, capacitors C11 to C16 and capacitors C10 to C40 included in the switched-capacitor circuit 20, capacitors C61 to C64 and a power inductor L71 included in the pre-regulator circuit 310, and capacitors C11 to C16 and capacitors C10 to C40 included in the switched-capacitor circuit 320.

In this way, the plurality of capacitors and the inductors disposed on the main surface 90a are grouped for the individual circuits and disposed around the integrated circuits 80 and 81.

Specifically, a group of the capacitors C61 to C64 and the power inductor L71 included in the pre-regulator circuit 310 is disposed in a region on the main surface 90a sandwiched between a straight line along the upper side of the integrated circuit 81 and a straight line along the upper side of the module laminate 90 in plan view of the module laminate 90. Accordingly, a group of the circuit components included in the pre-regulator circuit 310 is disposed near the PR switch portion 10B disposed in the upper part of the integrated circuit 81.

A group of the capacitors C11 to C16 and the capacitors C10 to C40 included in the switched-capacitor circuit 320 is disposed in a region on the main surface 90a sandwiched between a straight line along the left side of the integrated circuit 81 and a straight line along the left side of the module laminate 90, and a region on the main surface 90a sandwiched between a straight line along the lower side of the integrated circuit 81 and a straight line along the lower side of the module laminate 90, in plan view of the module laminate 90. Accordingly, a group of the circuit components included in the switched-capacitor circuit 320 is disposed near the SC switch portion 20B disposed in the lower part of the integrated circuit 81.

Accordingly, wiring loss in the pre-regulator circuit 310 and the switched-capacitor circuit 320 can be reduced, and power consumption can be reduced.

### 6. Implementation Example of Radio Frequency Module 1D According to Example 4

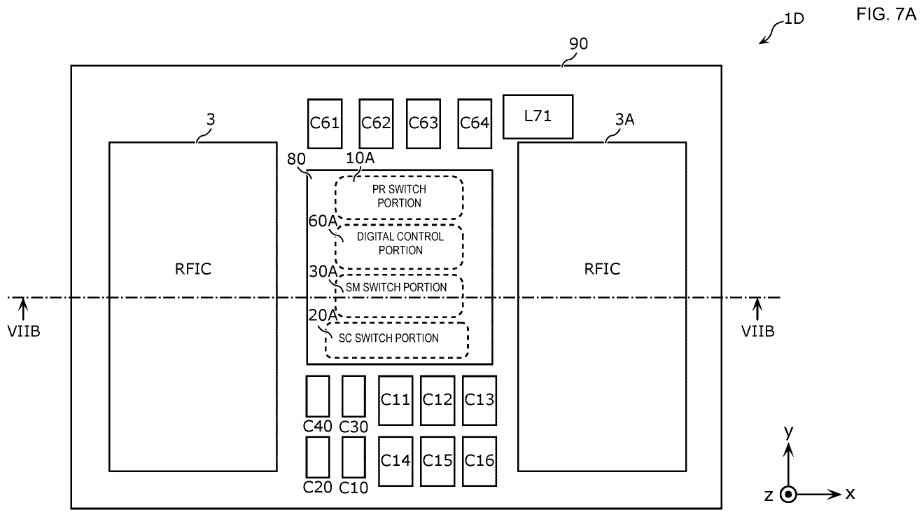

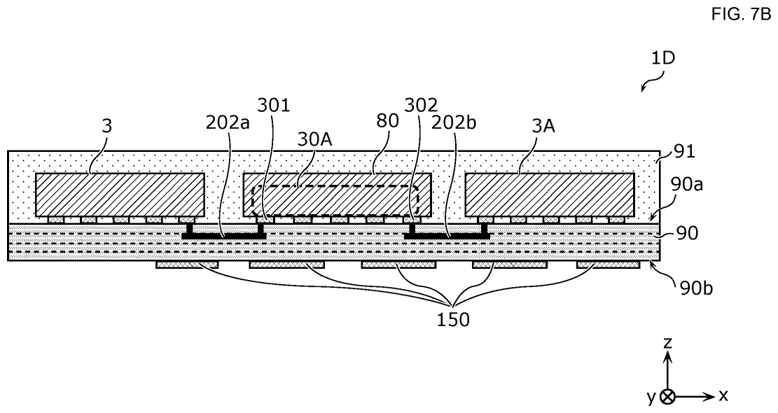

FIG. 7A is a plan view of a radio frequency module 1D according to Example 4. FIG. 7B is a cross-sectional view of the radio frequency module 1D according to Example 4. FIG. 7A illustrates a main surface 90a of a module laminate 90 viewed from the z-axis positive side. FIG. 7B illustrates a cross-section taken along line VIIB-VIIB in FIG. 7A.

As illustrated in FIG. 7A, the radio frequency module 1D includes the module laminate 90, RFICs 3 and 3A, and an integrated circuit 80. The radio frequency module 1D according to this example differs in the configuration from the radio frequency module 1A according to Example 1 in including the RFIC 3A. Hereinafter, regarding the radio frequency module 1D according to this example, descriptions of the same points as those of the radio frequency module 1A according to Example 1 will be omitted, and differences will be mainly described.

The integrated circuit 80 is an example of a first integrated circuit, and is at least one integrated circuit included in a tracker circuit 2. The integrated circuit 80 is disposed on the main surface 90a of the module laminate 90, and includes a PR switch portion 10A, an SC switch portion 20A, an SM switch portion 30A, and a digital control portion 60A. The PR switch portion 10A includes switches S61 to S63, S71, and S72 of the pre-regulator circuit 10. The SC switch portion 20A includes switches S11 to S14, S21 to S24, S31 to S34, and S41 to S44 of the switched-capacitor circuit 20. The SM switch portion 30A includes switches S51 to S54 of the supply modulator 30. The digital control portion 60A includes a digital control circuit.

It is sufficient that the integrated circuit 80 include the SC switch portion 20A and the SM switch portion 30A, and it may omit the PR switch portion 10A and the digital control portion 60A in an alternative exemplary aspect.

The RFIC 3 is an example of a first signal processing circuit, and is configured to output a radio frequency signal amplified by a first power amplifier (PA) that amplifies a radio frequency signal to an antenna. The RFIC 3 is disposed on the main surface 90a of the module laminate 90. It is noted that the RFIC 3 according to this example may omit the first PA.

The RFIC 3A is an example of a second signal processing circuit, and is configured to output a radio frequency signal amplified by a second power amplifier (PA) that amplifies a radio frequency signal to an antenna. The RFIC 3A is disposed on the main surface 90a of the module laminate 90. It is noted that the RFIC 3A according to this example may omit the second PA.

The tracker circuit 2 generates a supply voltage to the first PA and the second PA.

The RFIC 3 and the integrated circuit 80 are disposed adjacent to each other on the main surface 90a. The RFIC 3A and the integrated circuit 80 are disposed adjacent to each other on the main surface 90a. In plan view of the main surface 90a, the integrated circuit 80 is disposed between the RFIC 3 and the RFIC 3A.

With the above configuration, the radio frequency module 1D can be reduced in size, compared to a configuration in which the integrated circuit 80 and the RFICs 3 and 3A are individually disposed on a motherboard. Accordingly, a small radio frequency module 1D having an ET mode power amplifier system can be provided.

The radio frequency module 1D further includes capacitors C61 to C64 and a power inductor L71 included in the pre-regulator circuit 10, and capacitors C11 to C16 and capacitors C10 to C40 included in the switched-capacitor circuit 20.

The capacitors C61 to C64 and the power inductor L71, as well as the capacitors C11 to C16 and the capacitors C10 to C40 are disposed on the main surface 90a.

In this way, the plurality of capacitors and the inductor disposed on the main surface 90a are grouped for the individual circuits and disposed around the integrated circuit 80.

Specifically, a group of the capacitors C61 to C64 and the power inductor L71 included in the pre-regulator circuit 10 is disposed in a region on the main surface 90a sandwiched between a straight line along the upper side of the integrated circuit 80 and a straight line along the upper side of the module laminate 90 in plan view of the module laminate 90. Accordingly, a group of the circuit components included in the pre-regulator circuit 10 is disposed near the PR switch portion 10A disposed in the upper part of the integrated circuit 80.

A group of the capacitors C11 to C16 and the capacitors C10 to C40 included in the switched-capacitor circuit 20 is disposed in a region on the main surface 90a sandwiched between a straight line along the lower side of the integrated circuit 80 and a straight line along the lower side of the module laminate 90, in plan view of the module laminate 90. Accordingly, a group of the circuit components included in the switched-capacitor circuit 20 is disposed near the SC switch portion 20A disposed in the lower part of the integrated circuit 80.

Accordingly, wiring loss in the pre-regulator circuit 10 and the switched-capacitor circuit 20 can be reduced, and power consumption can be reduced.

In this example, the RFIC 3 may include the first PA, and the RFIC 3A may include the second power amplifier, and as illustrated in FIG. 7B, the integrated circuit 80 may include an output terminal 301 (first output terminal) for outputting a supply voltage to the first PA and an output terminal 302 (second output terminal) for outputting a supply voltage to the second PA. The output terminal 301 is different from the output terminal 302.

Accordingly, wiring 202a for supplying the supply voltage from the tracker circuit 2 to the first PA and wiring 202b for supplying the supply voltage from the tracker circuit 2 to the second PA can be shortened, and thus the supply voltages can be stabilized.

### 7. Implementation Example of Radio Frequency Module 1E According to Example 5

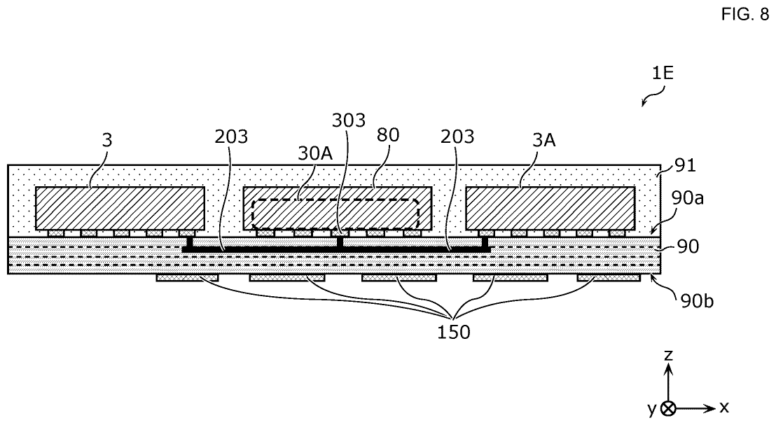

FIG. 8 is a cross-sectional view of a radio frequency module 1E according to Example 5. The radio frequency module 1E according to this example differs from the radio frequency module 1D according to Example 4 only in the configuration of the wiring for connecting the integrated circuit 80 to the RFICs 3 and 3A. Hereinafter, regarding the radio frequency module 1E according to this example, descriptions of the same points as those of the radio frequency module 1D according to Example 4 will be omitted, and differences will be mainly described.

In this example, the RFIC 3 includes a first power amplifier (PA), and the RFIC 3A includes a second PA. As illustrated in FIG. 8, the integrated circuit 80 has an output terminal 303 for outputting a supply voltage to the first PA and outputting a supply voltage to the second PA.

Accordingly, wiring 203 for supplying a supply voltage from the tracker circuit 2 to the first PA and wiring 203 for supplying a supply voltage from the tracker circuit 2 to the second PA can be standardized. Thus, the supply voltage from the tracker circuit 2 to the first PA and the supply voltage from the tracker circuit 2 to the second PA can be stabilized.

### 8. Implementation Example of Radio Frequency Module 1F According to Example 6

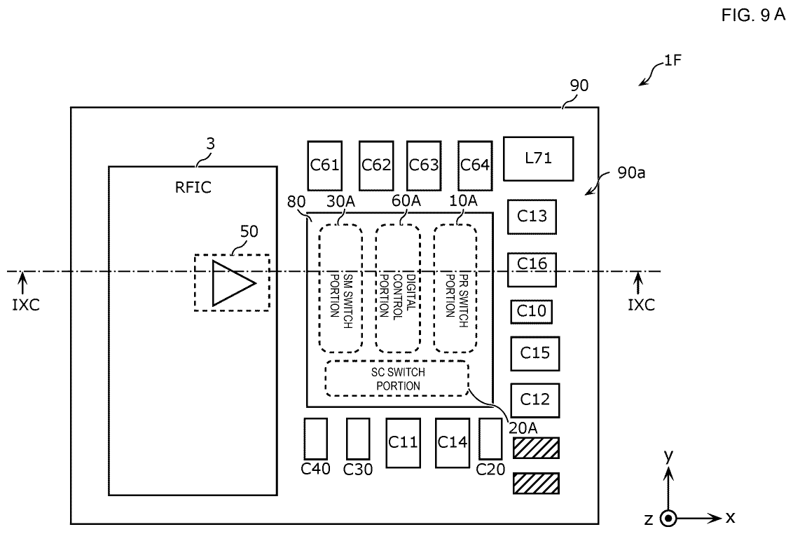

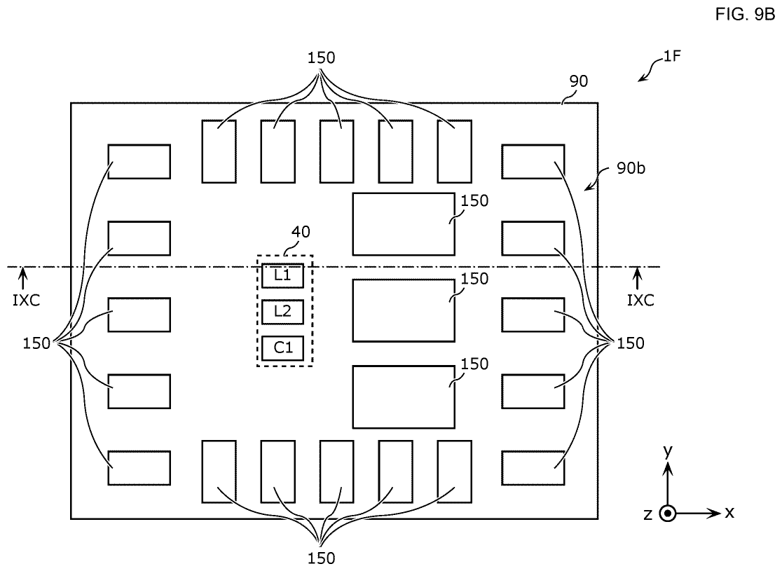

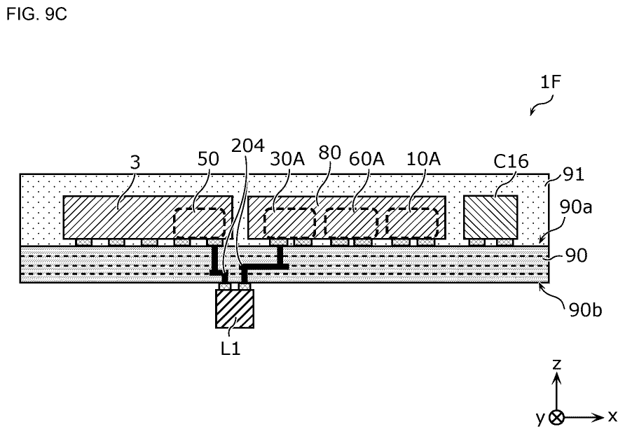

FIGS. 9A and 9B are plan views of a radio frequency module 1F according to Example 6. FIG. 9C is a cross-sectional view of the radio frequency module 1F according to Example 6. FIG. 9A illustrates a main surface 90a of a module laminate 90 viewed from the z-axis positive side. FIG. 9B is a transparent view of a main surface 90b of the module laminate 90 viewed from the z-axis positive side. FIG. 9C illustrates a cross-section taken along line IXC-IXC in FIGS. 9A and 9B.

As illustrated in FIGS. 9A and 9B, the radio frequency module 1F includes the module laminate 90, an RFIC 3, an integrated circuit 80, and a filter circuit 40. The radio frequency module 1F according to this example differs in the configuration from the radio frequency module 1B according to Example 2 in including the filter circuit 40. Hereinafter, regarding the radio frequency module 1F according to this example, descriptions of the same points as those of the radio frequency module 1B according to Example 2 will be omitted, and differences will be mainly described.

A tracker circuit 2 includes the filter circuit 40 connected between a supply modulator 30 and a power amplifier (PA) 50. The filter circuit 40 is configured to attenuate noise from a plurality of discrete voltages. The filter circuit 40 includes inductors L1 and L2 and a capacitor C1, for example.

The capacitor C1 is implemented as a chip capacitor. The implementation of the capacitor C1 is not limited to a chip capacitor. For example, the capacitor C1 may be included in an IPD.

The inductors L1 and L2 are each mounted as chip inductors. In an exemplary aspect, the chip inductor can be an SMD forming an inductor. The implementation of the inductors L1 and L2 is not limited to chip inductors. For example, some or all of the inductors L1 and L2 may be included in an IPD.

The inductors L1 and L2, and the capacitor C1 are disposed on the main surface 90b.

Accordingly, the PA 50 and the integrated circuit 80 are disposed adjacent to each other on the main surface 90a, and the filter circuit 40 is disposed on the main surface 90b. Thus, the radio frequency module 1F can be reduced in size.

As illustrated in FIG. 9C, in plan view of the module laminate 90, the RFIC 3 and the filter circuit 40 may at least partially overlap.

Accordingly, wiring 204 connecting the supply modulator 30 and the PA 50 via the filter circuit 40 can be shortened. Thus, a supply voltage from the tracker circuit 2 to the PA 50 can be stabilized.

A plurality of external connection terminals 150 are disposed on the main surface 90b. The plurality of external connection terminals 150 are electrically connected to a plurality of electronic components disposed on the main surface 90a through via conductors formed in the module laminate 90. The plurality of external connection terminals 150 may be, but are not limited to, bump electrodes and planar electrodes. For example, the plurality of external connection terminals 150 may be solder electrodes.

### 9. Implementation Example of Radio Frequency Module 1G According to Example 7

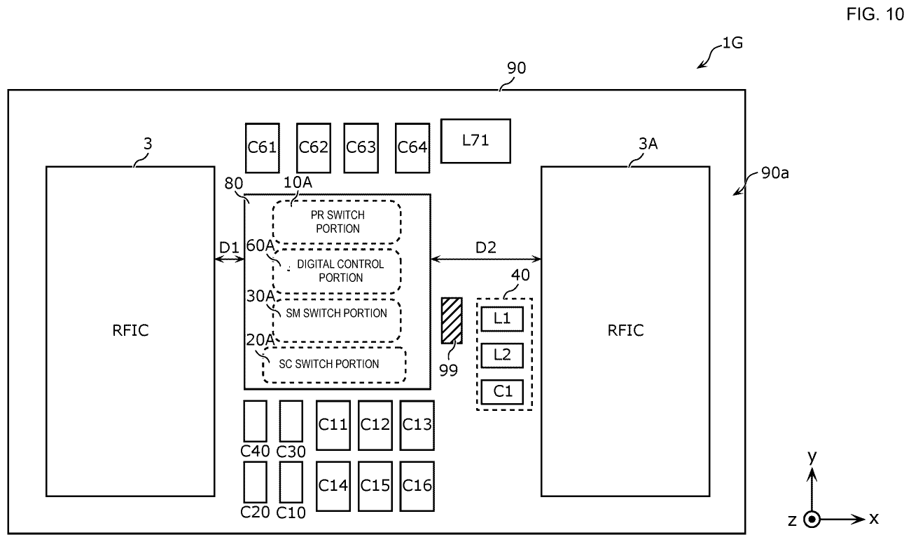

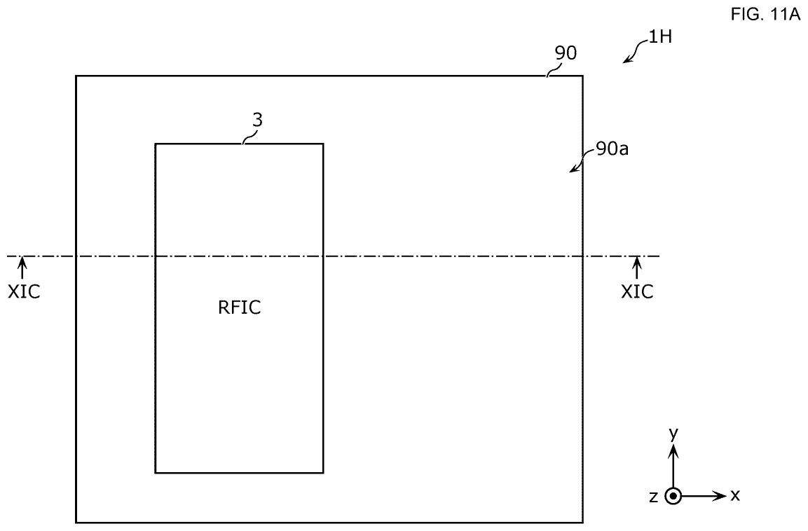

FIG. 10 is a plan view of a radio frequency module 1G according to Example 7. FIG. 10 illustrates a main surface 90a side of a module laminate 90 viewed from the z-axis positive side.

As illustrated in FIG. 10, the radio frequency module 1G includes the module laminate 90, RFICs 3 and 3A, an integrated circuit 80, and a filter circuit 40. The radio frequency module 1G according to this example differs in the configuration from the radio frequency module 1D according to Example 4 in including the filter circuit 40. Hereinafter, regarding the radio frequency module 1G according to this example, descriptions of the same points as those of the radio frequency module 1D according to Example 4 will be omitted, and differences will be mainly described.

The RFIC 3 includes a first power amplifier (PA), and the RFIC 3A includes a second PA.

A tracker circuit 2 includes the filter circuit 40 connected between a supply modulator 30 and the second PA. The filter circuit 40 is configured to attenuate noise from a plurality of discrete voltages. The filter circuit 40 includes inductors L1 and L2 and a capacitor C1, for example.

The capacitor C1 is implemented as a chip capacitor. The implementation of the capacitor C1 is not limited to a chip capacitor. For example, the capacitor C1 may be included in an IPD.

The inductors L1 and L2 are each mounted as chip inductors. In an exemplary aspect, the chip inductor can be an SMD forming an inductor. The implementation of the inductors L1 and L2 is not limited to chip inductors. For example, some or all of the inductors L1 and L2 may be included in an IPD.

The filter circuit 40 and a circuit component 99 are disposed between the RFIC 3A and the integrated circuit 80 on the main surface 90a. Here, a distance D2 between the integrated circuit 80 and the RFIC 3A is longer than a distance D1 between the integrated circuit 80 and the RFIC 3.

Accordingly, the RFIC 3 and the integrated circuit 80 are disposed adjacent to each other on the main surface 90a, and thus the radio frequency module 1G can be reduced in size.

Wiring connecting the integrated circuit 80 and the RFIC 3A is longer than wiring connecting the integrated circuit 80 and the RFIC 3 due to the presence of the filter circuit 40 and the circuit component 99. However, the filter circuit 40 is configured to suppress waveform rounding of the power supply voltage (a plurality of discrete voltages).

### 10. Implementation Example of Radio Frequency Module 1H According to Example 8

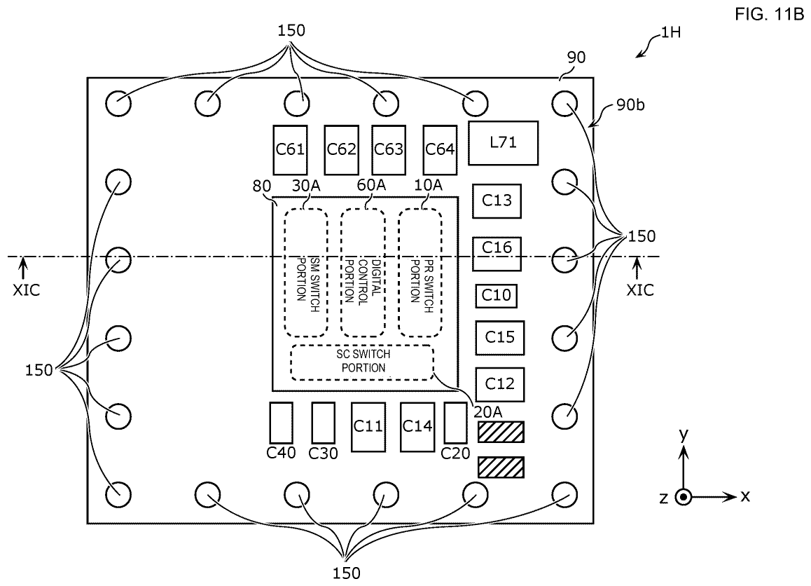

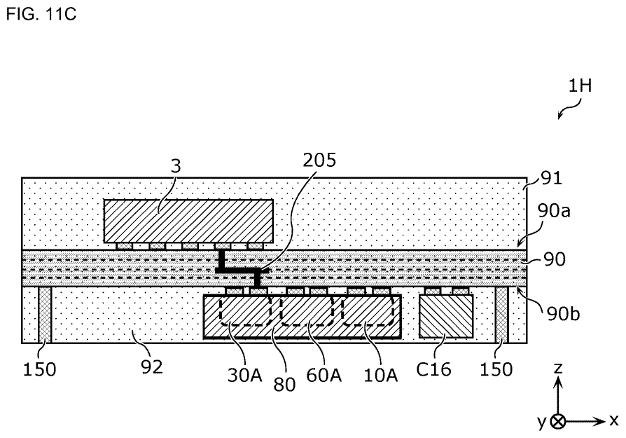

FIGS. 11A and 11B are plan views of a radio frequency module 1H according to Example 8. FIG. 11C is a cross-sectional view of the radio frequency module 1H according to Example 8. FIG. 11A illustrates a main surface 90a of a module laminate 90 viewed from the z-axis positive side. FIG. 11B is a transparent view of a main surface 90b of the module laminate 90 viewed from the z-axis positive side. FIG. 11C illustrates a cross-section taken along line XIC-XIC in FIGS. 11A and 11B.

As illustrated in FIGS. 11A and 11B, the radio frequency module 1H includes the module laminate 90, an RFIC 3, and an integrated circuit 80. The radio frequency module 1H according to this example differs from the radio frequency module 1A according to Example 1 in that the RFIC 3 and the integrated circuit 80 are disposed separately on both sides. Hereinafter, regarding the radio frequency module 1H according to this example, descriptions of the same points as those of the radio frequency module 1A according to Example 1 will be omitted, and differences will be mainly described.

A resin member 91 is disposed on the main surface 90a, covers the main surface 90a and some of a plurality of circuit components, and has a function to ensure reliability of the plurality of circuit components, such as mechanical strength and moisture resistance. A resin member 92 is disposed on the main surface 90b, covers the main surface 90b and some of the plurality of circuit components, and has a function to ensure reliability of the plurality of circuit components, such as mechanical strength and moisture resistance.

As illustrated in FIGS. 11A to 11C, the RFIC 3 is disposed on the main surface 90a, and the integrated circuit 80 is disposed on the main surface 90b.

Accordingly, the RFIC 3 and the integrated circuit 80 are disposed on the main surfaces 90a and 90b, respectively, and thus the radio frequency module 1H can be reduced in size.

A plurality of external connection terminals 150 are disposed on the main surface 90b. The plurality of external connection terminals 150 are electrically connected to a plurality of electronic components disposed on the main surfaces 90a and 90b through via conductors and planar conductors formed in the module laminate 90. The plurality of external connection terminals 150 may be, but are not limited to, copper electrodes. For example, the plurality of external connection terminals 150 may be solder electrodes.

The radio frequency module 1H further includes capacitors C61 to C64 and a power inductor L71 included in a pre-regulator circuit 10, and capacitors C11 to C16 and capacitors C10 to C40 included in a switched-capacitor circuit 20.

The capacitors C61 to C64 and the power inductor L71, as well as the capacitors C11 to C16 and the capacitors C10 to C40 are disposed on the main surface 90b.

The capacitors C61 to C64, the capacitors C11 to C16, and the capacitors C10 to C40 are each implemented as a chip capacitor. In an exemplary aspect, the chip capacitor can be an SMD forming a capacitor. The implementation of the plurality of capacitors is not limited to chip capacitors. For example, some or all of the plurality of capacitors may be included in an IPD, or may be included in the integrated circuit 80.

As illustrated in FIGS. 11A to 11C, in plan view of the module laminate 90, the RFIC 3 and the integrated circuit 80 at least partially overlap.

Accordingly, the radio frequency module 1H can be further reduced in size.

In the radio frequency module 1H, the RFIC 3 includes a first amplifying transistor of a power amplifier (PA) 50. In plan view of the module laminate 90, the first amplifying transistor and the integrated circuit 80 may at least partially overlap.

Accordingly, wiring 205 for supplying a supply voltage (a plurality of discrete voltages) from the tracker circuit 2 to the PA 50 can be shortened. Thus, the supply voltage can be stabilized.

### 11. Implementation Example of Radio Frequency Module 1J According to Example 9

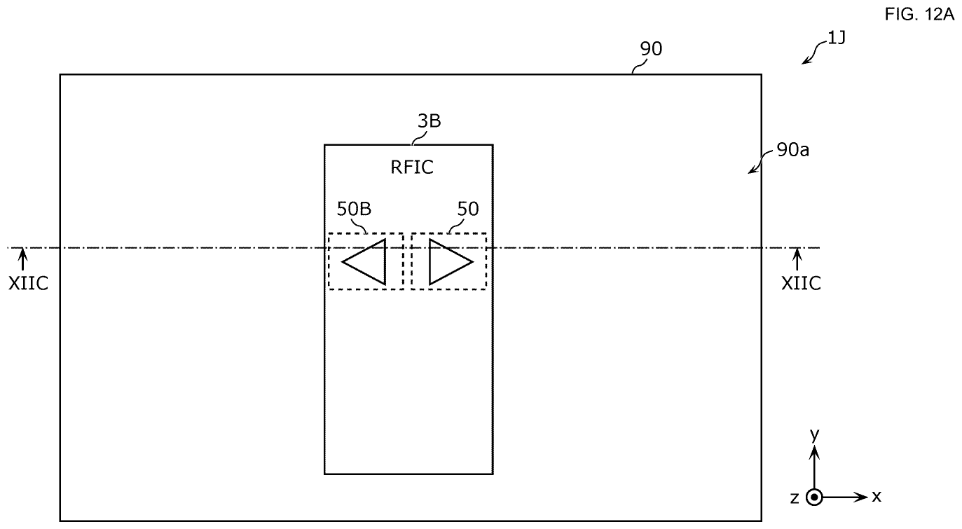

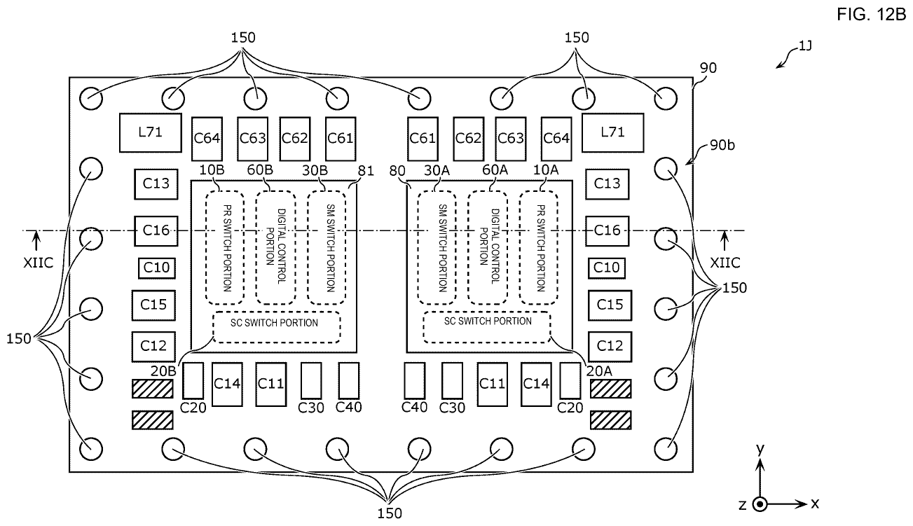

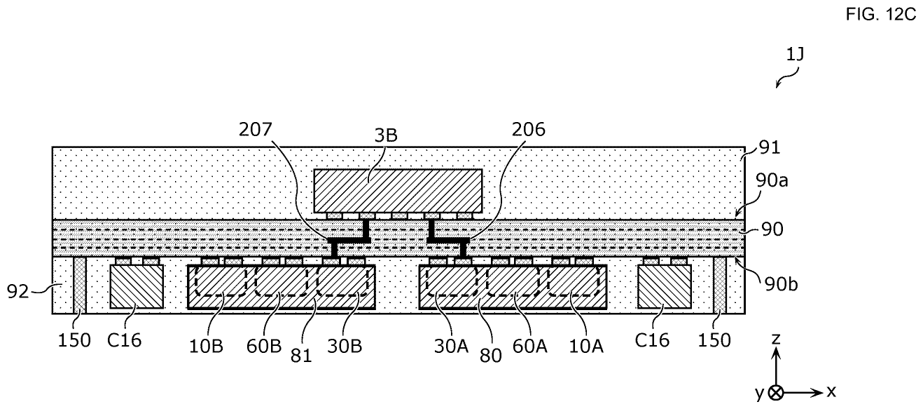

FIGS. 12A and 12B are plan views of a radio frequency module 1J according to Example 9. FIG. 12C is a cross-sectional view of the radio frequency module 1J according to Example 9. FIG. 12A illustrates a main surface 90a of a module laminate 90 viewed from the z-axis positive side. FIG. 12B is a transparent view of a main surface 90b of the module laminate 90 viewed from the z-axis positive side. FIG. 12C illustrates a cross-section taken along line XIIC-XIIC in FIGS. 12A and 12B.

As illustrated in FIGS. 12A and 12B, the radio frequency module 1J includes the module laminate 90, an RFIC 3B, and integrated circuits 80 and 81. The radio frequency module 1J according to this example differs from the radio frequency module 1C according to Example 3 in that the RFIC 3B and the integrated circuits 80 and 81 are disposed separately on both sides. Hereinafter, regarding the radio frequency module 1J according to this example, descriptions of the same points as those of the radio frequency module 1C according to Example 3 will be omitted, and differences will be mainly described.

A resin member 91 is disposed on the main surface 90a, covers the main surface 90a and some of a plurality of circuit components, and has a function to ensure reliability of the plurality of circuit components, such as mechanical strength and moisture resistance. A resin member 92 is disposed on the main surface 90b, covers the main surface 90b and some of a plurality of circuit components, and has a function to ensure reliability of the plurality of circuit components, such as mechanical strength and moisture resistance.

As illustrated in FIGS. 12A to 12C, the RFIC 3B is disposed on the main surface 90a, and the integrated circuits 80 and 81 are disposed on the main surface 90b.

Accordingly, the RFIC 3B and the integrated circuits 80 and 81 are disposed on the main surfaces 90a and 90b, respectively. Thus, the radio frequency module 1J can be reduced in size.

In plan view of the module laminate 90, a first amplifying transistor of a power amplifier (PA) 50 and the integrated circuit 80 at least partially overlap, and a second amplifying transistor of a PA 50B and the integrated circuit 81 at least partially overlap.

Accordingly, wiring 206 for supplying a supply voltage (a plurality of discrete voltages) from a tracker circuit 2 to the PA 50, and wiring 207 for supplying a supply voltage (a plurality of discrete voltages) from a second voltage supply circuit to the PA 50B can be shortened. Thus, the supply voltages can be stabilized.

A plurality of external connection terminals 150 are disposed on the main surface 90b. The plurality of external connection terminals 150 are electrically connected to a plurality of electronic components disposed on the main surfaces 90a and 90b through via conductors and planar conductors formed in the module laminate 90. The plurality of external connection terminals 150 may be, but are not limited to, copper electrodes. For example, the plurality of external connection terminals 150 may be solder electrodes.

### 12. Implementation Example of Radio Frequency Module 1K According to Example 10

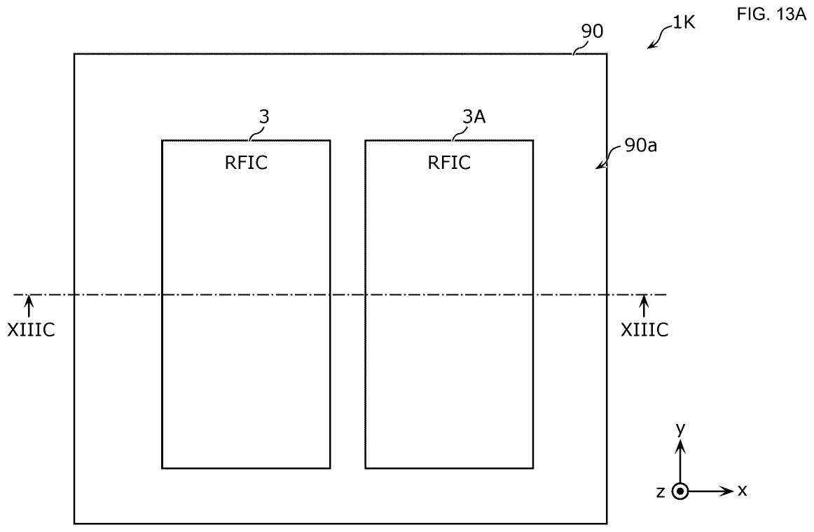

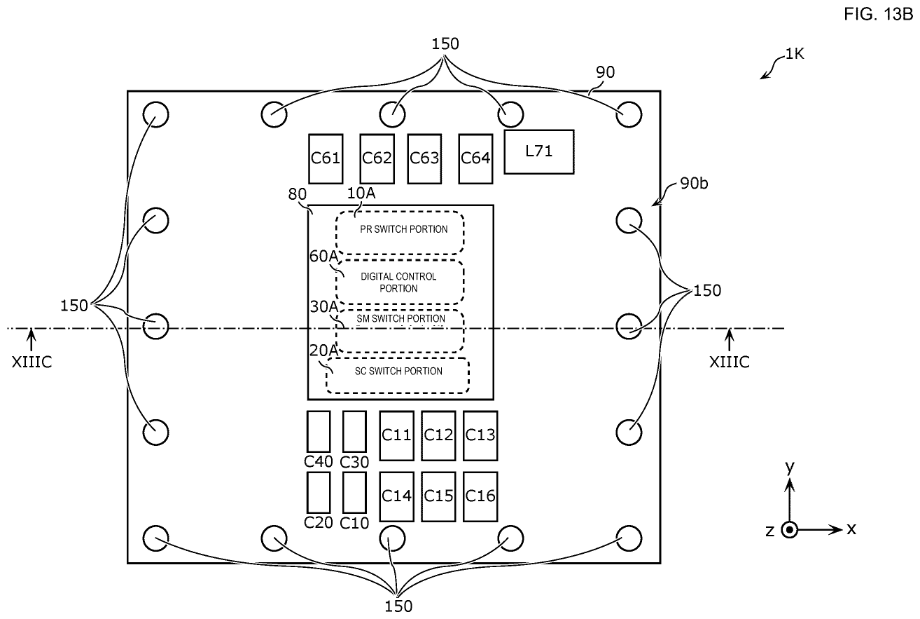

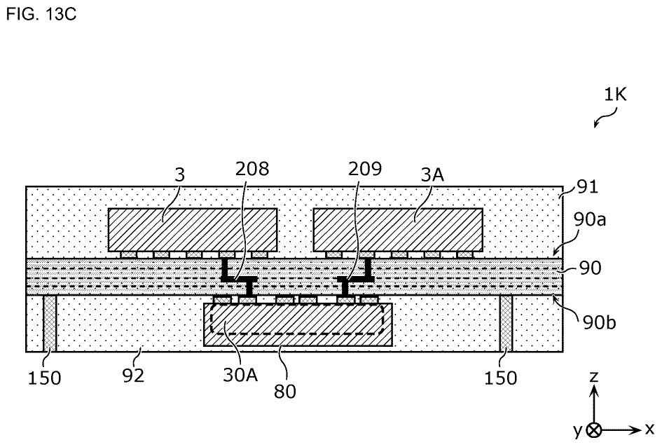

FIGS. 13A and 13B are plan views of a radio frequency module 1K according to Example 10. FIG. 13C is a cross-sectional view of the radio frequency module 1K according to Example 10. FIG. 13A illustrates a main surface 90a of a module laminate 90 viewed from the z-axis positive side. FIG. 13B is a transparent view of a main surface 90b of the module laminate 90 viewed from the z-axis positive side. FIG. 13C illustrates a cross-section taken along line XIIIC-XIIIC in FIGS. 13A and 13B.

As illustrated in FIGS. 13A and 13B, the radio frequency module 1K includes the module laminate 90, RFICs 3 and 3A, and an integrated circuit 80. The radio frequency module 1K according to this example differs from the radio frequency module 1D according to Example 4 in that the RFICs 3 and 3A and the integrated circuit 80 are disposed separately on both sides. Hereinafter, regarding the radio frequency module 1K according to this example, descriptions of the same points as those of the radio frequency module 1D according to Example 4 will be omitted, and differences will be mainly described.

A resin member 91 is disposed on the main surface 90a, covers the main surface 90a and some of a plurality of circuit components, and has a function to ensure reliability of the plurality of circuit components, such as mechanical strength and moisture resistance. The resin member 92 is disposed on the main surface 90b, covers the main surface 90b and some of the circuit components, and has the function of ensuring the reliability of the circuit components, such as mechanical strength and moisture resistance.

As illustrated in FIGS. 13A to 13C, the RFICs 3 and 3A are disposed on the main surface 90a, and the integrated circuit 80 is disposed on the main surface 90b.

Accordingly, the RFICs 3 and 3A and the integrated circuit 80 are disposed on the main surfaces 90a and 90b, respectively. Thus, the radio frequency module 1K can be reduced in size.

In plan view of the module laminate 90, the RFIC 3 and the integrated circuit 80 at least partially overlap, and the RFIC 3A and the integrated circuit 80 at least partially overlap.

Accordingly, wiring 208 for supplying a plurality of discrete voltages from a tracker circuit 2 to the RFIC 3 and wiring 209 for supplying a plurality of discrete voltages from the tracker circuit 2 to the RFIC 3A can be shortened. Thus, the supply voltages (the plurality of discrete voltages) can be stabilized.

In this example, the RFIC 3 may include a first power amplifier (PA), the RFIC 3A may include a second PA, and the integrated circuit 80 may include a first output terminal for outputting a supply voltage to the first PA and a second output terminal for outputting a supply voltage to the second PA. The first output terminal is different from the second output terminal.

Accordingly, wiring for supplying a supply voltage from the tracker circuit 2 to the first PA and wiring for supplying a supply voltage from the tracker circuit 2 to the second PA can be shortened. Thus, the supply voltages can be stabilized.

In this example, the RFIC 3 may include a first PA, the RFIC 3A may include a second PA, and the integrated circuit 80 may include an output terminal for outputting a supply voltage to the first PA and outputting a supply voltage to the second PA.

Accordingly, the supply voltage from the tracker circuit 2 to the first PA and the supply voltage from the tracker circuit 2 to the second PA can be stabilized.

### 13. Implementation Example of Radio Frequency Module 1L According to Example 11

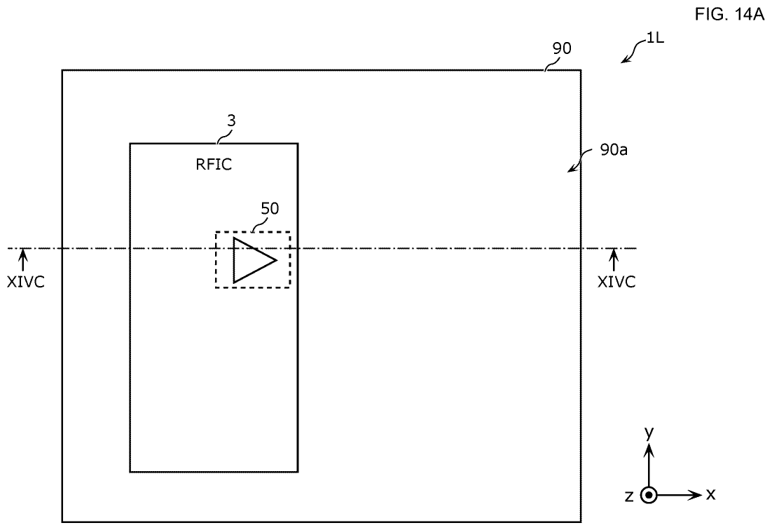

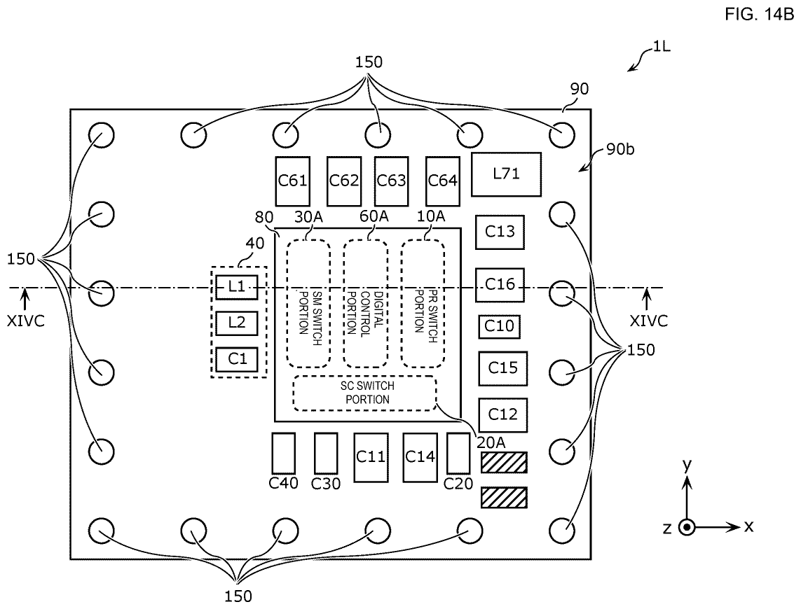

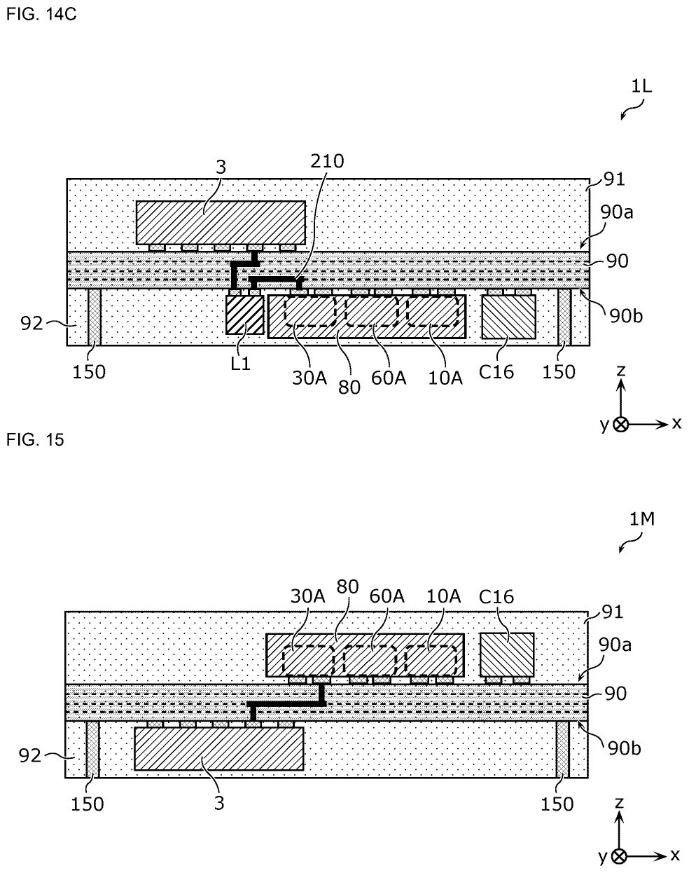

FIGS. 14A and 14B are plan views of a radio frequency module 1L according to Example 11. FIG. 14C is a cross-sectional view of the radio frequency module 1L according to Example 11. FIG. 14A illustrates a main surface 90a of a module laminate 90 viewed from the z-axis positive side. FIG. 14B is a transparent view of a main surface 90b of the module laminate 90 viewed from the z-axis positive side. FIG. 14C illustrates a cross-section taken along line XIVC-XIVC in FIGS. 14A and 14B.

As illustrated in FIGS. 14A and 14B, the radio frequency module 1L includes the module laminate 90, an RFIC 3, an integrated circuit 80, and a filter circuit 40. The radio frequency module 1L according to this example differs from the radio frequency module 1F according to Example 6 in that the RFIC 3, the integrated circuit 80, and the filter circuit 40 are disposed separately on both sides. Hereinafter, regarding the radio frequency module 1L according to this example, descriptions of the same points as those of the radio frequency module 1F according to Example 6 will be omitted, and differences will be mainly described.

A resin member 91 is disposed on the main surface 90a, covers the main surface 90a and some of a plurality of circuit components, and has a function to ensure reliability of the plurality of circuit components, such as mechanical strength and moisture resistance. A resin member 92 is disposed on the main surface 90b, covers the main surface 90b and some of a plurality of circuit components, and has a function to ensure reliability of the plurality of circuit components, such as mechanical strength and moisture resistance.

As illustrated in FIGS. 14A to 14C, the RFIC 3 is disposed on the main surface 90a, and the integrated circuit 80 and the filter circuit 40 are disposed on the main surface 90b.

Accordingly, the RFIC 3, the integrated circuit 80, and the filter circuit 40 are disposed on the main surfaces 90a and 90b, respectively. Thus, the radio frequency module 1L can be reduced in size.

As illustrated in FIG. 14C, in plan view of the module laminate 90, the RFIC 3 and the filter circuit 40 may at least partially overlap.

Accordingly, wiring 210 connecting a supply modulator 30 and a power amplifier (PA) 50 via the filter circuit 40 can be shortened. Thus, a supply voltage supplied from a tracker circuit 2 to the PA 50 can be stabilized.

A plurality of external connection terminals 150 are disposed on the main surface 90b. The plurality of external connection terminals 150 are electrically connected to a plurality of electronic components disposed on the main surfaces 90a and 90b through via conductors and planar conductors formed in the module laminate 90. The plurality of external connection terminals 150 may be, but are not limited to, copper electrodes. For example, the plurality of external connection terminals 150 may be solder electrodes.

### 14. Implementation Example of Radio Frequency Module 1M According to Example 12

FIG. 15 is a cross-sectional view of a radio frequency module 1M according to Example 12. As illustrated in FIG. 15, the radio frequency module 1M includes a module laminate 90, an RFIC 3, and an integrated circuit 80. The radio frequency module 1M according to this example differs from the radio frequency module 1H according to Example 8 in the arrangement of the RFIC 3 and the integrated circuit 80. Hereinafter, regarding the radio frequency module 1M according to this example, descriptions of the same points as those of the radio frequency module 1H according to Example 8 will be omitted, and differences will be mainly described.

As illustrated in FIG. 15, the integrated circuit 80 is disposed on the main surface 90a, and the RFIC 3 is disposed on the main surface 90b.

Accordingly, the integrated circuit 80 and the RFIC 3 are disposed on the main surfaces 90a and 90b, respectively. Thus, the radio frequency module 1M can be reduced in size.

In plan view of the module laminate 90, the integrated circuit 80 and the RFIC 3 at least partially overlap.

Accordingly, wiring for supplying a plurality of discrete voltages from a tracker circuit 2 to the RFIC 3 can be shortened. Thus, a supply voltage (a plurality of discrete voltages) can be stabilized.

### 15. Implementation Example of Communication Device According to Example 13

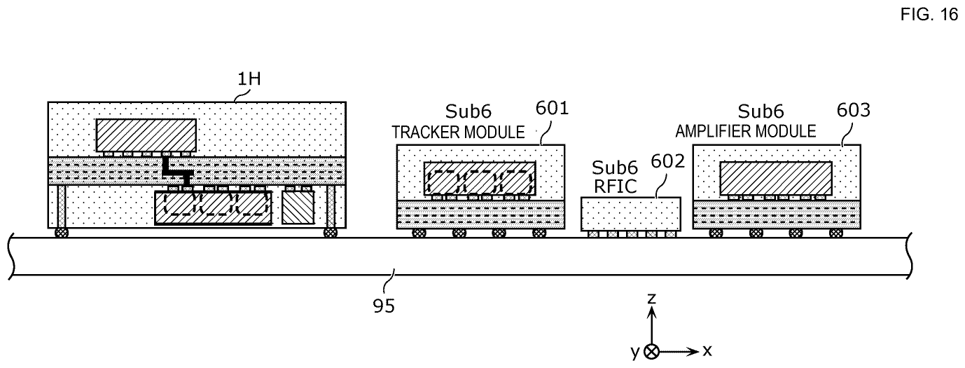

FIG. 16 is a cross-sectional view of a communication device according to Example 13. The communication device according to this example includes a motherboard 95, a radio frequency module 1H, a tracker module 601, an RFIC 602, and an amplifier module 603.

For example, the motherboard 95 may be, but is not limited to, an LTCC substrate or an HTCC substrate having a multilayer structure of a plurality of dielectric layers, a component-embedded board, a substrate having an RDL, or a printed circuit board.

The radio frequency module 1H is the radio frequency module 1H according to Example 8, and includes a module laminate 90, an RFIC 3, and an integrated circuit 80. The radio frequency module 1H is configured to amplify and transmitting signals of frequencies in the millimeter wave band or the sub-terahertz band.

In an exemplary aspect, the amplifier module 603 has a configuration in which a power amplifier (PA) configured to amplify signals in the Sub6 band (a frequency band of equal to or less than 6 GHz) is disposed on the module laminate.

Moreover, the tracker module 601 can be configured to supply a plurality of discrete voltages to the PA of the amplifier module 603, and has a configuration in which switches, capacitors, inductors, and the like are disposed on the module laminate.

The RFIC 602 is configured to supply the Sub6 signal to the PA of the amplifier module 603.

The radio frequency module 1H according to this example may be any of the radio frequency modules according to Examples 1 to 12.

With the above configuration, including the radio frequency module 1H reduced in size, the communication device can be reduced in size.

The radio frequency module 1H for amplifying and transmitting signals of frequencies in the millimeter wave band or the sub-terahertz band, and the tracker module 601, the RFIC 602, and the amplifier module 603 that supports the Sub6 signals are formed on different module laminates. Accordingly, this configuration reduces interference between the signals of frequencies in the millimeter wave band or the sub-terahertz band and the Sub6 signals.

### 16. Technical Effects

As described above, the radio frequency modules 1A to 1M according to the examples each include: the module laminate 90; the tracker circuit 2 configured to generate a supply voltage to the PA 50 that amplifies a radio frequency signal and composed of at least one integrated circuit; and the RFIC 3 configured to output the radio frequency signal to the antenna 200. The at least one integrated circuit includes at least one switch included in the switched-capacitor circuit 20 and at least one switch included in the supply modulator 30. The switched-capacitor circuit 20 is configured to generate a plurality of discrete voltages based on an input voltage and output the generated plurality of discrete voltages to the supply modulator 30. The supply modulator 30 is configured to selectively output at least one of the generated plurality of discrete voltages to the PA 50. The RFIC 3 and the at least one integrated circuit providing the tracker circuit 2 are disposed on the module laminate 90.

With the above configuration, the density of circuit components on the module laminate 90 in the above examples can be made higher than the density of circuit components on a motherboard in accordance with the design rules for the motherboard of the communication device 4, for example. Therefore, the radio frequency module according to the above examples can be reduced in size, compared to a configuration in which the integrated circuit and the RFIC 3 are individually disposed on the motherboard. Accordingly, this configuration provides a small radio frequency module and a small communication device having an ET mode power amplifier system.

In the radio frequency modules 1A to 1G, for example, the module laminate 90 has the main surfaces 90a and 90b facing each other, and the RFIC 3 and at least one integrated circuit providing the tracker circuit 2 are disposed adjacent to each other on the main surface 90a.

Accordingly, the radio frequency modules 1A to 1G can be further reduced in size.

In the radio frequency modules 1B, 1C, and 1F, for example, at least one integrated circuit providing the tracker circuit 2 includes the integrated circuit 80 including at least one switch included in the switched-capacitor circuit 20 and at least one switch included in the supply modulator 30. The RFIC 3 includes the PA 50. The PA 50 and the integrated circuit 80 are disposed adjacent to each other on the main surface 90a.

Accordingly, this configuration provides a small radio frequency module having an ET mode power amplifier system, and also to shorten the wiring for supplying the supply voltage (a plurality of discrete voltages) from the tracker circuit 2 to the PA 50. Thus, the supply voltage can be stabilized.

In the radio frequency module 1C, for example, the RFIC 3B further includes the PA 50B that amplifies a radio frequency signal. The radio frequency module 1C further includes the second voltage supply circuit configured to generate a supply voltage to the PA 50B and composed of at least the integrated circuit 81. The integrated circuit 81 includes at least one switch included in the switched-capacitor circuit 320 and at least one switch included in the supply modulator 330. The switched-capacitor circuit 320 is configured to generate a plurality of discrete voltages based on an input voltage and output the generated plurality of discrete voltages to the supply modulator 330. The supply modulator 330 is configured to selectively output at least one of the generated plurality of discrete voltages to the PA 50B. The PA 50B and the integrated circuit 81 are disposed adjacent to each other on the main surface 90a. In plan view of the main surface 90a, the RFIC 3B is disposed between the integrated circuit 80 and the integrated circuit 81.

Accordingly, the radio frequency module 1C can be reduced in size, compared with a case where the integrated circuits 80 and 81 and the RFIC 3B are disposed individually on a motherboard. Wiring for supplying a supply voltage (a plurality of discrete voltages) from the tracker circuit 2 to the PA 50 and wiring for supplying a supply voltage (a plurality of discrete voltages) from the second voltage supply circuit to the PA 50B can be shortened. Thus, the supply voltages can be stabilized.

In the radio frequency module 1C, for example, the PA 50 and the PA 50B are not connected in series.

For example, the radio frequency modules 1D and 1E each further include the RFIC 3A configured to output a radio frequency signal amplified by the second PA to the antenna. The tracker circuit 2 generates a supply voltage to the first PA and the second PA. The RFIC 3A and the integrated circuit 80 are disposed adjacent to each other on the main surface 90a. In plan view of the main surface 90a, the integrated circuit 80 is disposed between the RFIC 3 and the RFIC 3A.

Accordingly, the radio frequency modules 1D and 1E can be reduced in size, compared to a configuration in which the integrated circuit 80 and the RFICs 3 and 3A are individually disposed on the motherboard. Accordingly, this configuration provides small radio frequency modules 1D and 1E having an ET mode power amplifier system.

In the radio frequency module 1D, for example, the RFIC 3 includes the first PA, the RFIC 3A includes the second PA, and the integrated circuit 80 includes the output terminal 301 for outputting a supply voltage to the first PA and the output terminal 302 different from the output terminal 301, for outputting a supply voltage to the second PA.

Accordingly, the wiring for supplying the supply voltage from the tracker circuit 2 to the first PA and the wiring for supplying the supply voltage from the tracker circuit 2 to the second PA can be shortened. Thus, the supply voltages can be stabilized.

In the radio frequency module 1E, for example, the RFIC 3 includes the first PA, the RFIC 3A includes the second PA, and the integrated circuit 80 has the output terminal 303 for outputting a supply voltage to the first PA and outputting a supply voltage to the second PA.

Accordingly, the supply voltage from the tracker circuit 2 to the first PA and the supply voltage from the tracker circuit 2 to the second PA can be stabilized.

In the radio frequency module 1F, for example, the tracker circuit 2 includes the filter circuit 40 connected between the supply modulator 30 and the PA 50 and configured to attenuate noise from a plurality of discrete voltages. The filter circuit 40 is disposed on the main surface 90b.

Accordingly, since the PA 50 and the integrated circuit 80 are disposed adjacent to each other on the main surface 90a and the filter circuit 40 is disposed on the main surface 90b, the radio frequency module 1F can be reduced in size.

For example, the radio frequency module 1G further includes the RFIC 3A configured to output a radio frequency signal amplified by the second PA to the antenna. The RFIC 3A includes the second PA, and the tracker circuit 2 generates a supply voltage to the first PA and the second PA. The tracker circuit 2 includes the filter circuit 40 connected between the supply modulator 30 and the second PA and configured to attenuate noise from a plurality of discrete voltages. The filter circuit 40 is disposed between the RFIC 3A and the integrated circuit 80 on the main surface 90a. The distance D2 between the integrated circuit 80 and the RFIC 3A is longer than the distance D1 between the integrated circuit 80 and the RFIC 3.

Accordingly, the RFIC 3 and the integrated circuit 80 are disposed adjacent to each other on the main surface 90a. Thus, the radio frequency module 1G can be reduced in size. The wiring connecting the integrated circuit 80 and the RFIC 3A is longer than the wiring connecting the integrated circuit 80 and the RFIC 3 due to the presence of the filter circuit 40. However, the filter circuit 40 is configured to suppress waveform rounding of the power supply voltage.

In the radio frequency modules 1H to 1M, for example, the module laminate 90 has the first main surface and the second main surface that face each other, the RFIC 3 is disposed on the first main surface, and the integrated circuit 80 is disposed on the second main surface.

Accordingly, the integrated circuit 80 and the RFIC 3 are disposed on the first main surface and the second main surface, respectively. Thus, the radio frequency modules 1H to 1M can be reduced in size.

For example, the radio frequency modules 1H to 1M further include the plurality of external connection terminals 150. The plurality of external connection terminals 150 are disposed on the main surface 90b.

In the radio frequency modules 1H to 1M, for example, in plan view of the module laminate 90, the RFIC 3 and the integrated circuit 80 at least partially overlap.

Accordingly, the radio frequency modules 1H to 1M can be further reduced in size.

In the radio frequency modules 1H to 1M, for example, the RFIC 3 includes the first amplifying transistor of the PA 50. In plan view of the module laminate 90, the first amplifying transistor and the integrated circuit 80 at least partially overlap.

Accordingly, the wiring for supplying the supply voltage (a plurality of discrete voltages) from the tracker circuit 2 to the PA 50 can be shortened. Thus, the supply voltage can be stabilized.

In the radio frequency module 1J, for example, the RFIC 3B further includes the second amplifying transistor of the PA 50B that amplifies a radio frequency signal. The radio frequency module 1J further includes the second voltage supply circuit configured to generate a supply voltage to the PA 50B and composed of at least the integrated circuit 81. The integrated circuit 81 includes at least one switch included in the switched-capacitor circuit 320 and at least one switch included in the supply modulator 330. The switched-capacitor circuit 320 is configured to generate a plurality of discrete voltages based on an input voltage and output the generated plurality of discrete voltages to the supply modulator 330. The supply modulator 330 is configured to selectively output at least one of the generated plurality of discrete voltages to the PA 50B. The integrated circuits 80 and 81 are disposed on the main surface 90b. In plan view of the module laminate 90, the first amplifying transistor and the integrated circuit 80 at least partially overlap, and the second amplifying transistor and the integrated circuit 81 at least partially overlap.

Accordingly, the wiring 206 for supplying a supply voltage (a plurality of discrete voltages) from the tracker circuit 2 to the PA 50 and the wiring 207 for supplying a supply voltage (a plurality of discrete voltages) from the second voltage supply circuit to the PA 50B can be shortened. Thus, the supply voltages can be stabilized.

For example, the radio frequency module 1K further includes the RFIC 3A configured to output a radio frequency signal amplified by the second PA to the antenna. The tracker circuit 2 generates a supply voltage to the first PA and the second PA. The RFIC 3 and the RFIC 3A are disposed on the main surface 90a, and the integrated circuit 80 is disposed on the main surface 90b. In plan view of the module laminate 90, the RFIC 3 and the integrated circuit 80 at least partially overlap, and the RFIC 3A and the integrated circuit 80 at least partially overlap.

Accordingly, the wiring 208 for supplying a plurality of discrete voltages from the tracker circuit 2 to the RFIC 3 and the wiring 209 for supplying a plurality of discrete voltages from the tracker circuit 2 to the RFIC 3A can be shortened. Thus, the supply voltage (a plurality of discrete voltages) can be stabilized.

In the radio frequency module 1L, for example, the tracker circuit 2 has the filter circuit 40 connected between the supply modulator 30 and the PA 50 and configured to attenuate noise from the plurality of discrete voltages. The filter circuit 40 is disposed on the main surface 90b.

Accordingly, the RFIC 3, the integrated circuit 80, and the filter circuit 40 are disposed separately on the main surfaces 90a and 90b. Thus, the radio frequency module 1L can be reduced in size.

In the radio frequency module 1L, for example, the RFIC 3 includes the first amplifying transistor of the PA 50. In plan view of the module laminate 90, the first amplifying transistor and the filter circuit 40 at least partially overlap.

Accordingly, the wiring 210 connecting the supply modulator 30 and the PA 50 via the filter circuit 40 can be shortened. Thus, the supply voltage from the tracker circuit 2 to the PA 50 can be stabilized.

In the radio frequency modules 1A to 1M, for example, the above radio frequency is included in the millimeter wave band or the sub-terahertz band.

For example, the communication device 4 includes the motherboard, the antenna 200 disposed on the motherboard, and any one of the radio frequency modules 1A to 1M disposed on the motherboard and configured to transmit a radio frequency signal to the antenna.

Accordingly, the communication device 4 can realize the effects of the radio frequency modules 1A to 1M.

### Additional Exemplary Embodiments

The radio frequency module and the communication device according to the exemplary aspects of the present disclosure have been described above based on the embodiment. However, it is noted that the exemplary radio frequency module and the communication device are not limited to the above embodiment. The exemplary aspects of the present disclosure also includes other embodiments realized by combining any of the components in the above embodiment, modifications obtained by making various changes to the above embodiment that can be conceived by those skilled in the art without departing from the spirit of the present disclosure, and various devices including the radio frequency module and communication device described above.

For example, in the circuit configuration of the radio frequency module and the communication device according to each example, other circuit elements, wiring, and the like may be inserted between the paths connecting the circuit elements and signal paths disclosed in the drawings.

The exemplary aspects of the present disclosure can be widely used in a communication device such as a mobile phone, as a radio frequency module or communication device disposed in a front end portion compatible with the millimeter wave band or the sub-terahertz band.

### REFERENCE SIGNS LIST

1, 1A, 1B, 1C, 1D, 1E, 1F, 1G, 1H, 1J, 1K, 1L, 1M RADIO FREQUENCY MODULE
2 TRACKER CIRCUIT
3, 3A, 3B, 602 RFIC
4 COMMUNICATION DEVICE
10, 310 PRE-REGULATOR CIRCUIT
10A, 10B PR SWITCH PORTION
20, 320 SWITCHED-CAPACITOR CIRCUIT
20A, 20B SC SWITCH PORTION
30, 330 SUPPLY MODULATOR
30A, 30B SM SWITCH PORTION
40 FILTER CIRCUIT
50, 50B POWER AMPLIFIER (PA)
51 LOW-NOISE AMPLIFIER
52, 53 PHASE SHIFT CIRCUIT
54 SWITCH
60A, 60B DIGITAL CONTROL PORTION
80, 81 INTEGRATED CIRCUIT
90 MODULE LAMINATE
90a, 90b MAIN SURFACE
91, 92 RESIN MEMBER
95 MOTHERBOARD
110, 131, 132, 133, 134, 140 INPUT TERMINAL
111, 112, 113, 114, 130, 141 OUTPUT TERMINAL
150 EXTERNAL CONNECTION TERMINAL
200 ANTENNA
201, 202a, 202b, 203, 204, 205, 206, 207, 208, 209, 210 WIRING
300 BBIC
301, 302, 303 OUTPUT TERMINAL
400a, 400b MIXER
500 LOCAL OSCILLATOR
601 TRACKER MODULE
603 AMPLIFIER MODULE

1. A radio frequency module comprising:
a module laminate;
a first voltage supply circuit composed of at least one integrated circuit and configured to generate a supply voltage for a first power amplifier configured to amplify a radio frequency signal; and
a first signal processing circuit configured to output the radio frequency signal to an antenna,
wherein the at least one integrated circuit includes at least one switch included in a first switched-capacitor circuit and at least one switch included in a first supply modulator,
wherein the first switched-capacitor circuit is configured to generate a plurality of discrete voltages based on an input voltage and output the generated plurality of discrete voltages to the first supply modulator,
wherein the first supply modulator is configured to selectively output at least one discrete voltage of the generated plurality of discrete voltages to the first power amplifier, and
wherein the first signal processing circuit and the at least one integrated circuit are disposed on the module laminate.

2. The radio frequency module according to claim 1, wherein:
the module laminate has a first main surface and a second main surface that oppose each other, and
the first signal processing circuit and the at least one integrated circuit are disposed adjacent to each other on the first main surface.

3. The radio frequency module according to claim 2, wherein:
the at least one integrated circuit composing the first voltage supply circuit includes a first integrated circuit including at least one switch included in the first switched-capacitor circuit and at least one switch included in the first supply modulator,
the first signal processing circuit includes the first power amplifier, and
the first power amplifier is disposed adjacent to the first integrated circuit on the first main surface.

4. The radio frequency module according to claim 3, wherein:
the first signal processing circuit further includes a second power amplifier configured to amplify a radio frequency signal,
the radio frequency module further comprises a second voltage supply circuit composed of at least a second integrated circuit and configured to generate a supply voltage to the second power amplifier,
the second integrated circuit includes at least one switch included in a second switched-capacitor circuit and at least one switch included in a second supply modulator,
the second switched-capacitor circuit is configured to generate a plurality of discrete voltages based on an input voltage and output the generated plurality of discrete voltages to the second supply modulator,
the second supply modulator is configured to selectively output at least one discrete voltage of the generated plurality of discrete voltages to the second power amplifier,
the second power amplifier is disposed adjacent to the second integrated circuit on the first main surface, and
the first signal processing circuit is disposed between the first integrated circuit and the second integrated circuit in a plan view of the first main surface.

5. The radio frequency module according to claim 4, wherein the first power amplifier and the second power amplifier are not connected in series to each other.

6. The radio frequency module according to claim 2, further comprising:
a second signal processing circuit configured to output a radio frequency signal amplified by a second power amplifier to the antenna,
wherein the first voltage supply circuit is configured to generate a supply voltage to the first power amplifier and the second power amplifier,
wherein the second signal processing circuit and the at least one integrated circuit are disposed adjacent to each other on the first main surface, and
wherein the at least one integrated circuit composing the first voltage supply circuit is disposed between the first signal processing circuit and the second signal processing circuit in a plan view of the first main surface.

7. The radio frequency module according to claim 6, wherein:
the first signal processing circuit includes the first power amplifier,
the second signal processing circuit includes the second power amplifier,
the at least one integrated circuit composing the first voltage supply circuit includes a first integrated circuit including at least one switch included in the first switched-capacitor circuit and at least one switch included in the first supply modulator, and
the first integrated circuit includes a first output terminal configured to output a supply voltage to the first power amplifier, and a second output terminal different from the first output terminal and configured to output a supply voltage to the second power amplifier.

8. The radio frequency module according to claim 6, wherein:
the first signal processing circuit includes the first power amplifier,
the second signal processing circuit includes the second power amplifier,
the at least one integrated circuit composing the first voltage supply circuit includes a first integrated circuit including at least one switch included in the first switched-capacitor circuit and at least one switch included in the first supply modulator, and
the first integrated circuit includes an output terminal configured to output a supply voltage to the first power amplifier and to output a supply voltage to the second power amplifier.

9. The radio frequency module according to claim 3, wherein:
the first voltage supply circuit has a filter circuit connected between the first supply modulator and the first power amplifier and is configured to attenuate noise from the plurality of discrete voltages, and
the filter circuit is disposed on the second main surface.

10. The radio frequency module according to claim 3, further comprising:
a second signal processing circuit configured to output a radio frequency signal amplified by a second power amplifier to the antenna,
wherein the second signal processing circuit includes the second power amplifier,
wherein the first voltage supply circuit is configured to generate a supply voltage to the first power amplifier and the second power amplifier,
wherein the first voltage supply circuit includes a filter circuit connected between the first supply modulator and the second power amplifier and is configured to attenuate noise from the plurality of discrete voltages,
wherein the filter circuit is disposed between the second signal processing circuit and the first integrated circuit on the first main surface, and
wherein a distance between the first integrated circuit and the second signal processing circuit is longer than a distance between the first integrated circuit and the first signal processing circuit.

11. The radio frequency module according to claim 1, wherein:
the module laminate has a first main surface and a second main surface that oppose each other,
the first signal processing circuit is disposed on the first main surface, and
the at least one integrated circuit is disposed on the second main surface.

12. The radio frequency module according to claim 11, further comprising a plurality of external connection terminals that are disposed on the second main surface.

13. The radio frequency module according to claim 11, wherein in a plan view of the module laminate, the first signal processing circuit and the at least one integrated circuit at least partially overlap each other.

14. The radio frequency module according to claim 11, wherein:
the at least one integrated circuit composing the first voltage supply circuit includes a first integrated circuit including at least one switch included in the first switched-capacitor circuit and at least one switch included in the first supply modulator,
the first signal processing circuit includes a first amplifying transistor of the first power amplifier, and
the first amplifying transistor and the first integrated circuit at least partially overlap each other in a plan view of the module laminate.

15. The radio frequency module according to claim 14, wherein:
the first signal processing circuit further includes a second amplifying transistor of a second amplifier that amplifies a radio frequency signal,
the radio frequency module further comprises a second voltage supply circuit composed of at least a second integrated circuit and configured to generate a supply voltage to the second power amplifier,
the second integrated circuit includes at least one switch included in a second switched-capacitor circuit and at least one switch included in a second supply modulator,
the second switched-capacitor circuit is configured to generate a plurality of discrete voltages based on an input voltage and output the generated plurality of discrete voltages to the second supply modulator,
the second supply modulator is configured to selectively output at least one discrete voltage of the generated plurality of discrete voltages to the second power amplifier,
the first integrated circuit and the second integrated circuit are disposed on the second main surface, and
in the plan view of the module laminate, the first amplifying transistor and the first integrated circuit at least partially overlap each other, and the second amplifying transistor and the second integrated circuit at least partially overlap each other.

16. The radio frequency module according to claim 11, further comprising:
a second signal processing circuit configured to output a radio frequency signal amplified by a second power amplifier to the antenna,
wherein the first voltage supply circuit is configured to generate a supply voltage to the first power amplifier and the second power amplifier,
wherein the first signal processing circuit and the second signal processing circuit are disposed on the first main surface,
wherein the at least one integrated circuit composing the first voltage supply circuit is disposed on the second main surface, and
wherein in a plan view of the module laminate, the first signal processing circuit and the at least one integrated circuit at least partially overlap each other, and the second signal processing circuit and the at least one integrated circuit at least partially overlap each other.

17. The radio frequency module according to claim 11, wherein:
the first voltage supply circuit has a filter circuit connected between the first supply modulator and the first power amplifier and is configured to attenuate noise from the plurality of discrete voltages, and
the filter circuit is disposed on the second main surface.

18. The radio frequency module according to claim 17, wherein:
the at least one integrated circuit composing the first voltage supply circuit includes a first integrated circuit including at least one switch included in the first switched-capacitor circuit and at least one switch included in the first supply modulator,
the first signal processing circuit includes a first amplifying transistor of the first power amplifier, and
the first amplifying transistor and the filter circuit at least partially overlap each other in a plan view of the module laminate.

19. The radio frequency module according to claim 1, wherein the radio frequency is in a millimeter wave band or a sub-terahertz band.

20. A communication device comprising:
a motherboard; and
the radio frequency module according to claim 1,
wherein the radio frequency module is disposed on the motherboard and configured to transmit a radio frequency signal to an antenna.
